(19) United States
(12) Patent Application Publication
(10) Pub. No.: US 2025/0287576 A1
(43) Pub. Date: Sep. 11, 2025

(54) SEMICONDUCTOR MEMORY DEVICE

(71) Applicant: Samsung Electronics Co., Ltd., Suwon-si (KR)

(72) Inventors: Byung Keun KIM, Suwon-si (KR); Sang Wan KIM, Suwon-si (KR); Dong Joo MIN, Suwon-si (KR); Seung Jin JEONG, Suwon-si (KR); Min Woo CHO, Suwon-si (KR); Young-Hoo KIM, Suwon-si (KR)

(73) Assignee: Samsung Electronics Co., Ltd., Suwon-si (KR)

(21) Appl. No.: 18/825,289

(22) Filed: Sep. 5, 2024

(30) Foreign Application Priority Data
Mar. 6, 2024 (KR) 10-2024-0031920

(51) Int. Cl. H10B 12/00

(52) U.S. Cl. CPC H10B 12/488; H10B 12/315; H10B 12/482; H10B 12/50

(57) ABSTRACT

A semiconductor memory device includes a bit-line on the substrate and extending in a first direction, a liner film on the bit-line and extending along an upper surface of the bit-line, a channel structure on the liner film, the channel structure including first and a second channel patterns apart from each other in the first direction, liner patterns between the liner film and the channel structure, each of the liner patterns overlapping the channel structure when viewed in a plan view, a first word-line between the first and second channel patterns, the first word-line extending in a second direction, a second word-line between the first and second channel patterns, the second word-line extending in the second direction and apart from the first word-line in the first direction, and first and second capacitors on the first and second channel patterns, respectively, and connected to the first and second channel patterns, respectively.

### CROSS-REFERENCE TO RELATED APPLICATION

This application claims priority from Korean Patent Application No. 10-2024-0031920 filed on Mar. 6, 2024 in the Korean Intellectual Property Office, and all the benefits accruing therefrom under 35 U.S.C. 119, the contents of which in its entirety are herein incorporated by reference.

### BACKGROUND

### Technical Field

The present disclosure relates to semiconductor memory devices, and more specifically, to semiconductor memory devices including a vertical channel transistor (VCT).

### Description of Related Art

In order to meet high performance and low price of a semiconductor memory device as demanded by consumers, it is required to increase integration of the semiconductor memory device. The integration of the semiconductor memory device is an important factor in determining a price thereof. Thus, the semiconductor memory device particularly having increased integration is required.

Integration of a two-dimensional (2D) or planar semiconductor memory device is largely determined based on an occupancy area of a unit memory cell, and therefore is greatly affected by a level of a fine pattern formation skill. However, ultra-expensive equipment is required for formation of fine patterns. Thus, although the integration of the 2D semiconductor memory device is increasing, the increase thereof is limited. Accordingly, a semiconductor memory device including a vertical channel transistor in which a channel extends in a vertical direction is being proposed.

### SUMMARY

Some example embodiments of the present disclosure provide semiconductor memory devices with improved electrical characteristics.

Some example embodiments of the present disclosure are not limited to the above-mentioned example embodiments. Other example embodiments of the present disclosure that are not mentioned may be understood based on following descriptions of some example embodiments. Further, it will be easily understood that example embodiments of the present disclosure may be realized using means illustrated in the claims and combinations thereof.

According to an example embodiment of the present disclosure, a semiconductor memory device may include a bit-line on a substrate and extending in a first direction, a liner film on the bit-line and extending along an upper surface of the bit-line, a channel structure on the liner film, the channel structure including a first channel pattern and a second channel pattern that are spaced apart from each other in the first direction, a plurality of liner patterns between the liner film and the channel structure, each of the liner patterns overlapping the channel structure when viewed in a plan view, a first word-line between the first channel pattern and the second channel pattern, the first word-line extending in a second direction intersecting the first direction, a second word-line between the first channel pattern and the second channel pattern, the second word-line extending in the second direction, the second word-line spaced apart from the first word-line in the first direction, and a first capacitor and a second capacitor on the first channel pattern and the second channel pattern, respectively, the first capacitor and the second capacitor connected to the first channel pattern and the second channel pattern, respectively.

According to an example embodiment of the present disclosure, a semiconductor memory device may include a bit-line on a substrate and extending in a first direction, the bit-line including first metal, a liner film on the bit-line and extending along an upper surface of the bit-line, the liner film including second metal different from the first metal, a channel structure on the liner film, the channel structure including a first channel pattern and a second channel pattern that are spaced apart from each other in the first direction, a plurality of liner patterns between the liner film and the channel structure, each of the liner patterns including oxide of the second metal, a first word-line between the first channel pattern and the second channel pattern, the first word-line extending in a second direction intersecting the first direction, a second word-line between the first channel pattern and the second channel pattern, the second word-line extending in the second direction, the second word-line spaced apart from the first word-line in the first direction, and a first capacitor and a second capacitor on the first channel pattern and the second channel pattern, respectively, and the first capacitor and the second capacitor connected to the first channel pattern and the second channel pattern, respectively.

According to an example embodiment of the present disclosure, a semiconductor memory device may include a peripheral gate structure on a substrate, a bit-line on the peripheral gate structure, the bit line extending in the first direction, the bit-line including first metal, a liner film on the bit-line, the liner film extending along an upper surface of the bit-line, the liner film including second metal different from the first metal, a channel structure on the liner film, the channel structure including a first channel pattern and a second channel pattern that are spaced apart from each other in the first direction, a liner pattern between the liner film and the channel structure, the liner pattern including oxide of the second metal doped with niobium, a first word-line between the first channel pattern and the second channel pattern, the first word-line extending in the second direction intersecting the first direction, a second word-line between the first channel pattern and the second channel pattern, the second word-line extending in the second direction, the second word-line spaced apart from the first word-line in the first direction, a first capacitor and a second capacitor on the first channel pattern and the second channel pattern, respectively, the first capacitor and the second capacitor connected to the first channel pattern and the second channel pattern, respectively, and a gate isolation pattern on the liner pattern, the gate isolation pattern isolating the first word-line and the second word-line from each other.

It should be noted that the effects of the present disclosure are not limited to those described above, and other effects of the present disclosure will be apparent from the following description.

### BRIEF DESCRIPTION OF DRAWINGS

The above and other aspects and features of the present disclosure will become more apparent by describing in detail some example embodiments thereof with reference to the attached drawings, in which:

FIG. 1 is a layout diagram for illustrating a semiconductor memory device according to an example embodiment of the present disclosure.

FIG. 2 is a cross-sectional view cut along lines A-A and B-B in FIG. 1.

FIG. 3 is a cross-sectional view cut along lines C-C and D-D in FIG. 1.

FIG. 4 is an enlarged view of a P portion of FIG. 2.

FIGS. 5 to 9 are diagrams for illustrating a semiconductor memory device according to some example embodiments of the present disclosure.

FIG. 10 is a diagram for illustrating a semiconductor memory device according to an example embodiment of the present disclosure.

FIG. 11 and FIG. 12 are diagrams for illustrating a semiconductor memory device according to an example embodiment of the present disclosure.

FIGS. 13 to 16 are diagrams for illustrating semiconductor memory devices according to an example embodiment of the present disclosure.

FIGS. 17 to 42 are diagrams for illustrating a semiconductor memory device manufacturing method according to an example embodiment of the present disclosure.

### DETAILED DESCRIPTIONS

In this specification, although terms such as “first,” “second,” “upper,” and “lower” are used to describe various elements or components, these elements or components are not limited by these terms. These terms are merely used to distinguish one element or component from another. Therefore, a first element or component mentioned below may be a second element or component within the technical spirit of the present disclosure. Similarly, a lower element or component mentioned below may be an upper element or component within the technical spirit of the present disclosure.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various example embodiments are illustrated and described further below. It will be understood that the description herein is not intended to limit the claims to the specific example embodiments described. On the contrary, it is intended to cover alternatives, modifications, and equivalents as may include within the spirit and scope of the present disclosure as defined by the appended claims.

A shape, a size, a ratio, an angle, a number, etc. disclosed in the drawings for illustrating some example embodiments of the present disclosure are illustrative, and the present disclosure is not limited thereto. The same reference numerals refer to the same elements herein. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

The terminology used herein is for the purpose of describing particular example embodiments only and is not intended to limit the present disclosure. As used herein, the singular forms “a” and “an” are intended to include the plural forms as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of the associated listed items. Expression such as “at least one of” when preceding a list of elements may modify the entirety of list of elements and may not modify the individual elements of the list. When referring to “C to D”, this means C inclusive to D inclusive unless otherwise specified.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described under could be termed a second element, component, region, layer or section, without departing from the spirit and scope of the present disclosure.

In addition, it will also be understood that when a first element or layer is referred to as being present “on” or “beneath” a second element or layer, the first element may be disposed directly on or beneath the second element or may be disposed indirectly on or beneath the second element with a third element or layer being disposed between and connected to the first and second elements or layers. It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only one element or layer between the two elements or layers, or one or more intervening elements or layers may also be present.

Hereinafter, some example embodiments of the present disclosure will be described in detail with reference to the accompanying drawings. The same reference numerals are used for the same components in the drawings, and duplicate descriptions thereof are omitted.

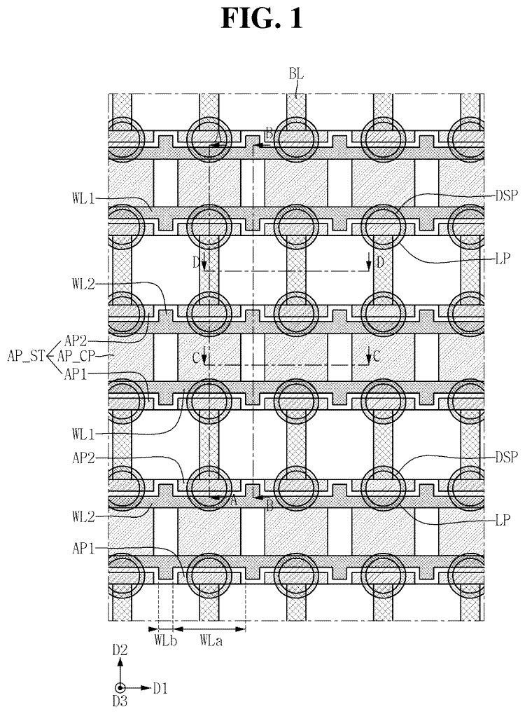

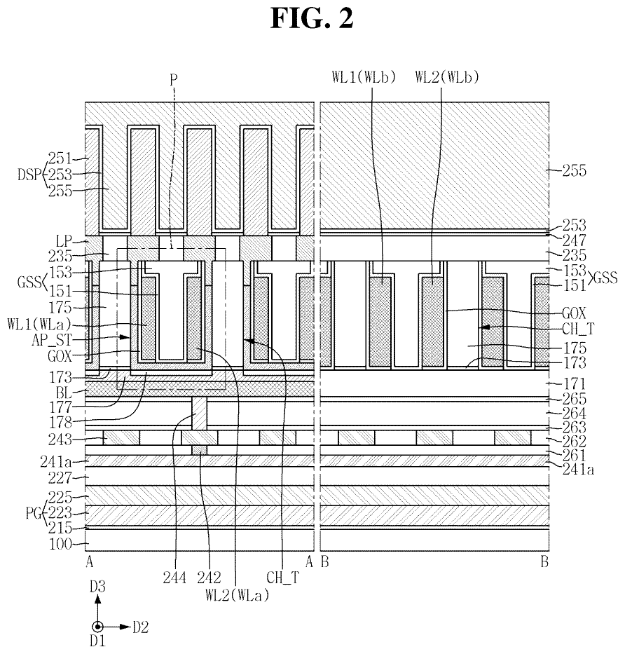

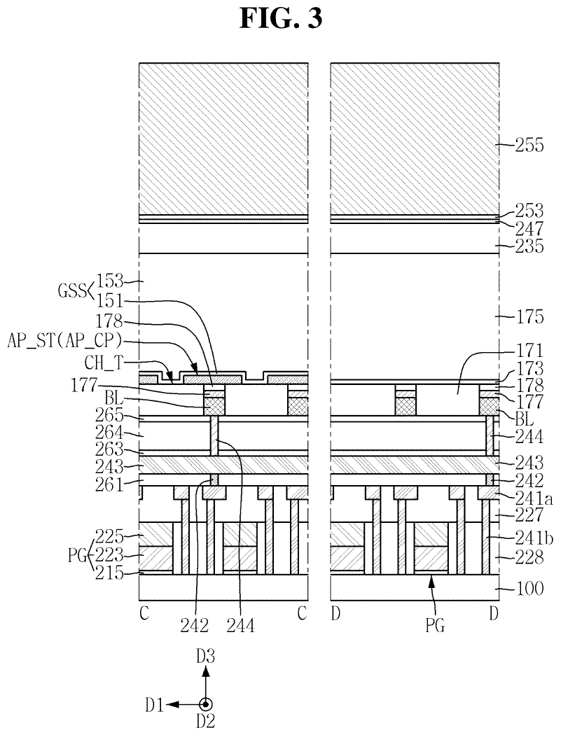

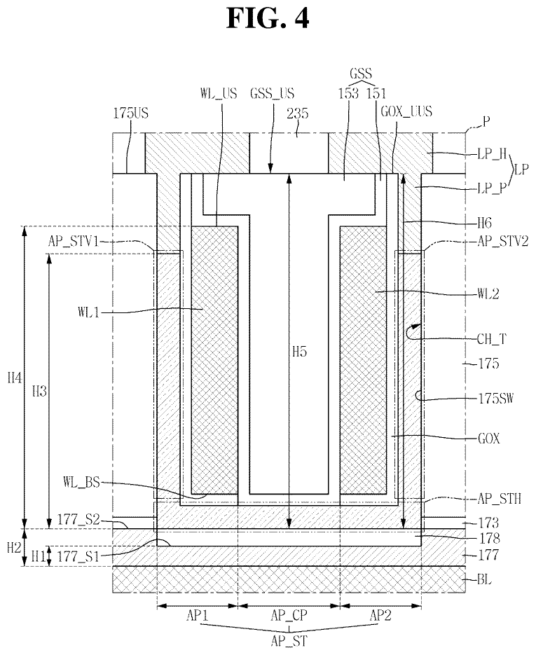

FIG. 1 is a layout diagram for illustrating a semiconductor memory device according to an example embodiment of the present disclosure. FIG. 2 is a cross-sectional view cut along lines A-A and B-B in FIG. 1. FIG. 3 is a cross-sectional view cut along lines C-C and D-D in FIG. 1. FIG. 4 is an enlarged view of a P portion of FIG. 2. An example embodiment embodiments of the present disclosure is described with reference to FIGS. 1 to 4.

A semiconductor memory device according to an example embodiment of the present disclosure may include memory cells, each including a vertical channel transistor (VCT).

Referring to FIGS. 1 to 4, the semiconductor memory device according to an example embodiment of the present disclosure may include a substrate 100, a peripheral gate structure PG, bit-lines BL, a liner film 177, a liner pattern 178, word-lines WL1 and WL2, channel structures AP_ST, a protruding insulating pattern 175, and a data storage pattern DSP.

The substrate 100 may be a silicon substrate, or may include a material other than silicon, such as silicon germanium, indium antimonide, lead telluride compound, indium arsenide, indium phosphide, gallium arsenide, or gallium antimonide. However, example embodiments of the present disclosure are not limited thereto.

The peripheral gate structure PG may be disposed on the substrate 100. The substrate 100 may include a cell array area and a peripheral circuit area. The peripheral gate structure PG may be disposed across and on the cell array area and the peripheral circuit area. In other words, a portion of the peripheral gate structure PG may be disposed on the cell array area of the substrate 100, and the remainder of the peripheral gate structure PG may be disposed on the peripheral circuit area of the substrate 100.

The peripheral gate structure PG may be included in a sensing transistor, a transfer transistor, and a driving transistor. A type of a transistor disposed in each of the cell array area and the peripheral circuit area may vary depending on a design layout of the semiconductor memory device.

The peripheral gate structure PG may include a peripheral gate insulating film 215, a peripheral lower conductive pattern 223, and a peripheral upper conductive pattern 225.

The peripheral gate insulating film 215 may include a silicon oxide film, a silicon oxynitride film, a high dielectric constant insulating film having a higher dielectric constant than that of the silicon oxide film, or a combination thereof. The high dielectric constant insulating film may include, but is not limited to, at least one of, for example, metal oxide, metal oxynitride, metal silicon oxide, or metal silicon oxynitride.

Each of the peripheral lower conductive pattern 223 and the peripheral upper conductive pattern 225 may include a conductive material. For example, each of the peripheral lower conductive pattern 223 and the peripheral upper conductive pattern 225 may include at least one of doped semiconductor material, conductive metal nitride, conductive metal silicon nitride, metal carbonitride, conductive metal silicide, conductive metal oxide, ad two-dimensional material (2D material), metal, or metal alloy. The peripheral gate structure PG is shown as including a plurality of conductive patterns. However, example embodiments of the present disclosure are not limited thereto.

In a semiconductor memory device according to some example embodiments, the two-dimensional material may be a metallic material and/or a semiconductor material. The two-dimensional material may include two-dimensional allotrope or two-dimensional compound. For example, the two-dimensional material may include, but is not limited to, at least one of graphene, molybdenum disulfide (MoS₂), molybdenum diselenide (MoSe₂), tungsten diselenide (WSe₂), or tungsten disulfide (WS₂). That is, the above-described two-dimensional materials are only listed by way of example. The two-dimensional material that may be included in the semiconductor device according to the present disclosure is not limited to the above-described materials.

The first peripheral lower insulating film 227 and the second peripheral lower insulating film 228 may be disposed on the substrate 100. Each of the first peripheral lower insulating film 227 and the second peripheral lower insulating film 228 may be made of an insulating material.

A first peripheral wiring line 241a and a peripheral contact plug 241b may be disposed within the first peripheral lower insulating film 227 and the second peripheral lower insulating film 228. Although the first peripheral wiring line 241a and the peripheral contact plug 241b are shown as different films, embodiments of the present disclosure are not limited thereto. a boundary between the first peripheral wiring line 241a and the peripheral contact plug 241b may not be defined. Each of the first peripheral wiring line 241a and the peripheral contact plug 241b may include a conductive material.

A first peripheral upper insulating film 261 and a second peripheral upper insulating film 262 may be disposed on the first peripheral wiring line 241a and the peripheral contact plug 241b. Each of the first peripheral upper insulating film 261 and the second peripheral upper insulating film 262 may be made of an insulating material.

A second peripheral wiring line 243 and a peripheral via plug 242 may be disposed on the first peripheral wiring line 241a. The peripheral via plug 242 may be disposed within the first peripheral upper insulating film 261. The second peripheral wiring line 243 may be disposed within the second peripheral upper insulating film 262.

The second peripheral wiring line 243 and the peripheral via plug 242 may be connected to the first peripheral wiring line 241a. The peripheral via plug 242 may connect the first peripheral wiring line 241a and the second peripheral wiring line 243 to each other. Each of the second peripheral wiring line 243 and the peripheral via plug 242 may include a conductive material. The second peripheral wiring line 243 and the peripheral via plug 242 are shown as different films. However, example embodiments of the present disclosure are not limited thereto. A boundary between the second peripheral wiring line 243 and the peripheral via plug 242 may not be defined.

A third peripheral upper insulating film 263, a fourth peripheral upper insulating film 264, and a fifth peripheral upper insulating film 265 may be sequentially disposed on the second peripheral wiring line 243. Each of the third peripheral upper insulating film 263, the fourth peripheral upper insulating film 264, and the fifth peripheral upper insulating film 265 may be made of an insulating material.

The fourth peripheral upper insulating film 264 may be made of an insulating material different from that of each of the third peripheral upper insulating film 263 and the fifth peripheral upper insulating film 265. For example, the fourth peripheral upper insulating film 264 may be made of an oxide-based insulating material, and each of the third peripheral upper insulating film 263 and the fifth peripheral upper insulating film 265 may be made of a nitride-based insulating material. However, example embodiments of the present disclosure are not limited thereto.

The cell connection plug 244 may be disposed within the third peripheral upper insulating film 263, the fourth peripheral upper insulating film 264, and the fifth peripheral upper insulating film 265. The cell connection plug 244 may be connected to the second peripheral wiring line 243. The cell connection plug 244 may include a conductive material. The cell connection plug 244 may be disposed in a peripheral upper insulating film as a single film.

The bit-lines BL may be disposed on the peripheral gate structure PG. For example, the bit-lines BL may be disposed on the fifth peripheral upper insulating film 265. For example, the bit-lines BL may contact the fifth peripheral upper insulating film 265.

The bit-line BL may extend in an elongated manner in a second direction D2. Adjacent bit-lines BL may be spaced apart from each other in a first direction D1. The bit-line BL may include a long sidewall extending in the second direction D2 and a short sidewall extending in the first direction D1.

Although not shown, each bit-line BL may extend from the cell array area to the peripheral circuit area. An end of each bit-line BL may be disposed on the peripheral circuit area of the substrate 100.

Each bit-line BL may be disposed on the cell connection plug 244. Each bit-line BL may include, at least one of, for example, doped semiconductor material, conductive metal nitride, conductive metal silicon nitride, metal carbonitride, conductive metal silicide, conductive metal oxide, two-dimensional material, metal, or metal alloy. Although each bit-line BL is shown as being embodied as a single film, example embodiments of the present disclosure are not limited thereto.

A cell lower insulating film 171 may be disposed on the fifth peripheral upper insulating film 265. The cell lower insulating film 171 may be disposed between the bit-lines BL spaced apart from each other in the first direction D1. The cell lower insulating film 171 may be made of or include an insulating material.

The liner film 177 may be disposed on the bit-line BL. The liner film 177 may extend along an upper surface of the bit-line BL. The liner film 177 may cover the upper surface of the bit-line BL. The liner film 177 may include conductive metal nitride. For example, the liner film 177 may include titanium nitride (TiN). In some example embodiments, the liner film 177 may include metal. For example, the liner film 177 may include at least one of Zn, In, or Ni. In some example embodiments, the liner film 177 may include a different type of metal from a type of the metal included in the bit-line BL.

A plurality of liner patterns 178 may be disposed on the liner film 177. The liner pattern 178 may be disposed between the channel structure AP_ST, which will be described later and the liner film 177. The liner pattern 178 may overlap the channel structure AP_ST in a third direction D3 (e.g., when viewed in a plan view). The plurality of liner patterns 178 may be arranged to be spaced apart from each other in the second direction D2. The bit-line BL, the liner film 177, and the liner pattern 178 may be sequentially stacked in the third direction D3.

The liner film 177 may include a first surface 177_S1 in contact with the liner pattern 178 and a second surface 177_S2 overlapping, in the third direction D3, with a protruding insulating pattern 175 to be described later. A vertical length H1 of the first surface 177_S1 based on the bit-line BL may be smaller than a vertical length H2 of the second surface 177_S2 based on the bit-line BL. In other words, the vertical length H1 from the bit-line BL to the first surface 177_S1 may be smaller than the vertical length H2 from the bit-line BL to the second surface 177_S2.

The second surface 177_S2 of the liner film 177 and the upper surface of the liner pattern 178 may be coplanar with each other. However, example embodiments of the present disclosure are not limited thereto.

In some example embodiments, when the liner film 177 includes metal, the liner pattern 178 may include oxide of the metal included in the liner film 177. For example, when the liner film 177 includes titanium nitride (TiN), the liner pattern 178 may include titanium oxide (TiOₓ). In this case, a Schottky barrier height of an interface between the liner pattern 178 and the channel structure AP_ST may be lowered, so that contact resistance may be improved.

In some example embodiments, the liner pattern 178 may include titanium oxide doped with niobium (Nb). The niobium-doped titanium oxide film may be a film made of titanium oxide doped with niobium. In some example embodiments, the niobium-doped titanium oxide may be an oxide of titanium and niobium. When the liner pattern 178 is doped with niobium, the liner pattern 178 has surplus electrons, so that electrical conductivity may be improved. Further, in some example embodiments, the liner pattern 178 may include titanium oxide seeded with silicon (Si). The titanium oxide seeded with silicon (Si) may be made of a film in which silicon is seeded on titanium oxide. When the liner pattern 178 is seeded with silicon, the liner pattern 178 may have oxidation resistance, thereby mitigating preventing the liner pattern 178 from being oxidized toward the liner film 177.

The protruding insulating pattern 175 may be disposed on the liner film 177 and the cell lower insulating film 171. A cell lower etch stop film 173 may be disposed between the protruding insulating pattern 175 and the cell lower insulating film 171. Further, the cell lower etch stop film 173 may be disposed between the protruding insulating pattern 175 and the liner film 177.

Each of the protruding insulating pattern 175 and the cell lower etch stop film 173 may be made of an insulating material. The cell lower etch stop film 173 may include a material having an etch selectivity relative to the protruding insulating pattern 175. For example, the protruding insulating pattern 175 may be made of an oxide-based insulating material. However, example embodiments of the present disclosure are not limited thereto. In some example embodiments, the cell lower etch stop film 173 may not be disposed between the protruding insulating pattern 175 and the cell lower insulating film 171.

The protruding insulating pattern 175 may not overlap the liner pattern 178 in the third direction D3. The protruding insulating pattern 175 may not overlap the liner pattern 178 in the second direction D2. The protruding insulating pattern 175 may overlap with the liner pattern 178 in the first direction D1.

The protruding insulating pattern 175 may include a plurality of channel trenches CH_T. Each channel trench CH_T may extend in an elongated manner in the first direction D1. Adjacent channel trenches CH_T may be spaced apart from each other in the second direction D2.

Each channel trench CH_T may intersect the bit-line BL and the liner film 177. One channel trench CH_T may expose the plurality of liner patterns 178.

A bottom surface of each channel trench CH_T may be defined by the liner pattern 178 and the cell lower insulating film 171. A sidewall of each channel trench CH_T may be defined by the protruding insulating pattern 175 and the cell lower etch stop film 173. At least a portion of the sidewall of the channel trench CH_T may be a sidewall 175SW of the protruding insulating pattern 175. When the cell lower etch stop film 173 is not disposed, the sidewall of each channel trench CH_T may be defined by the protruding insulating pattern 175.

The channel structure AP_ST may be disposed on a corresponding bit-line BL. The channel structure AP_ST may be disposed on a corresponding liner film 177. The channel structure AP_ST may be disposed on the plurality of liner patterns 178. The plurality of channel structures AP_ST may be electrically connected to one liner film 177. The plurality of channel structure AP_ST may be directly connected to one liner pattern 178. Adjacent ones of the plurality of channel structures AP_ST disposed on one liner film 177 may be spaced apart from each other in the second direction D2.

The channel structure AP_ST may be disposed within a channel trench CH_T extending in the first direction D1. The plurality of channel structures AP_ST may be disposed within one channel trench CH_T. The plurality of channel structures AP_ST disposed within the channel trench CH_T may be spaced apart from each other in the first direction D1.

For example, the channel structure AP_ST may be arranged two-dimensionally along the first direction D1 and the second direction D2 that intersect each other.

The channel structure AP_ST may extend along a sidewall and a bottom surface of the channel trench CH_T. In a cross-sectional view as cut in the second direction D2, the channel structure AP_ST may have a “U” shape.

The channel structure AP_ST may include a horizontal portion AP_STH, a first vertical portion AP_STV1, and a second vertical portion AP_STV2. The first vertical portion AP_STV1 of the channel structure AP_ST and the second vertical portion AP_STV2 of the channel structure AP_ST may protrude in the third direction D3 from the horizontal portion AP_STH of the channel structure AP_ST.

The horizontal portion AP_STH of the channel structure AP_ST may extend along the bottom surface of the channel trench CH_T. In a cross-sectional view as cut in the second direction D2, the horizontal portion AP_STH of the channel structure AP_ST may extend along the upper surface of the liner pattern 178. The horizontal portion AP_STH of the channel structure AP_ST may be directly connected to the liner pattern 178. In some example embodiments, the horizontal portion AP_STH of the channel structure AP_ST may contact the upper surface of the bit-line BL.

The first vertical portion AP_STV1 of the channel structure AP_ST and the second vertical portion AP_STV2 of the channel structure AP_ST may extend along the sidewall of the channel trench CH_T. In the cross-sectional view as cut in the second direction D2, each of the first vertical portion AP_STV1 of the channel structure AP_ST and the second vertical portion AP_STV2 of the channel structure AP_ST may extend along the sidewall 175SW of the protruding insulating pattern 175.

The channel structure AP_ST may include oxide semiconductor material. For example, the channel structure AP_ST may include metal oxide. The metal oxide may include, for example, one of indium gallium zinc oxide (IGZO), indium zinc oxide (IZO) doped with impurities, indium oxide (InO), zinc oxide (ZnO), gallium oxide (GaO), tin oxide (SnO), aluminum zinc oxide (AZO), or indium tin oxide (ITO). In indium zinc oxide (IZO) doped with the impurities, the doped impurity may include at least one of, for example, magnesium (Mg), strontium (Sr), barium (Ba), scandium (Sc), yttrium (Y), lanthanum (La), titanium (Ti), zirconium (Zr), hafnium (Hf), aluminum (Al), tin (Sn), or tantalum (Ta).

The channel structure AP_ST may include a first channel pattern AP1, a second channel pattern AP2, and a connection channel pattern AP_CP. The connection channel pattern AP_CP may connect the first channel pattern AP1 and the second channel pattern AP2 to each other. The first channel pattern AP1 and the second channel pattern AP2 may be spaced apart from each other in the second direction D2.

The first channel pattern AP1, the second channel pattern AP2, and the connection channel pattern AP_CP may be disposed on the liner pattern 178. The first channel pattern AP1, the second channel pattern AP2, and the connection channel pattern AP_CP may be connected to the liner pattern 178. The first channel pattern AP1, the second channel pattern AP2, and the connection channel pattern AP_CP may be in direct contact with the upper surface of the liner pattern 178.

The first channel pattern AP1 may include a portion of the horizontal portion AP_STH of the channel structure AP_ST and the first vertical portion AP_STV1 of the channel structure AP_ST. The portion of the horizontal portion AP_STH of the channel structure AP_ST may be a horizontal portion of the first channel pattern AP1. The first vertical portion AP_STV1 of the channel structure AP_ST may be a vertical portion of the first channel pattern AP1.

The second channel pattern AP2 may include another portion of the horizontal portion AP_STH of the channel structure AP_ST and the second vertical portion AP_STV2 of the channel structure AP_ST. The another portion of the horizontal portion AP_STH of the channel structure AP_ST may be a horizontal portion of the second channel pattern AP2. The second vertical portion AP_STV2 of the channel structure AP_ST may be a vertical portion of the second channel pattern AP2.

The connection channel pattern AP_CP includes the remainder of the horizontal portion AP_STH of the channel structure AP_ST. In other words, the connection channel pattern AP_CP includes the remainder of the horizontal portion AP_STH of the channel structure AP_ST other than that of the horizontal portion included in the first channel pattern AP1 and the horizontal portion included in the second channel pattern AP2.

Based on the first word-line WL1 and the second word-line WL2, which will be described later, the first channel pattern AP1, the second channel pattern AP2, and the connection channel pattern AP_CP may be distinguished from each other. For example, in FIG. 4, the first word-line WL1 is described by way of example. The first word-line WL1 may include an inner sidewall facing the sidewall 175SW of the protruding insulating pattern 175, and an outer sidewall that is opposite to the inner sidewall in the second direction D2. A boundary between the first channel pattern AP1 and the connection channel pattern AP_CP may coincide with an extension line of the outer sidewall of the first word-line WL1 extending in the third direction D3. In another example, the second word-line WL2 may include an inner sidewall facing the sidewall 175SW of the protruding insulating pattern 175, and an outer sidewall that is opposite to the inner sidewall in the second direction D2. A boundary between the second channel pattern AP2 and the connection channel pattern AP_CP may coincide with an extension line of the outer sidewall of the second word-line WL2 extending in the third direction D3.

In the semiconductor memory device according to some example embodiments, each of the first channel pattern AP1, the second channel pattern AP2, and the connection channel pattern AP_CP may include metal oxide.

The first word-line WL1 and the second word-line WL2 may be disposed on the channel structure AP_ST. The first word-line WL1 and the second word-line WL2 may be disposed in the channel trench CH_T.

Each of the first word-line WL1 and the second word-line WL2 may extend in the first direction D1. The first word-lines WL1 and the second word-lines WL2 may be alternately arranged with each other in the second direction D2. The first word-line WL1 may be spaced apart from the second word-line WL2 in the second direction D2.

The first word-line WL1 and the second word-line WL2 may be spaced apart from the bit-line BL and the liner film 177 in the third direction D3. The first word-line WL1 and the second word-line WL2 may intersect the bit-line BL. In some example embodiments, the first word-line WL1 and the second word-line WL2 may intersect the liner film 177.

The first word-line WL1 and the second word-line WL2 may be disposed on the horizontal portion AP_STH of the channel structure AP_ST. The first word-line WL1 and the second word-line WL2 may be disposed between the first vertical portion AP_STV1 of the channel structure AP_ST and the second vertical portion AP_STV2 of the channel structure AP_ST.

The first word-line WL1 may be disposed on the first channel pattern AP1. The second word-line WL2 may be disposed on the second channel pattern AP2. The first word-line WL1 and the second word-line WL2 may be disposed between the first channel pattern AP1 and the second channel pattern AP2. The first channel pattern AP1 may be disposed closer to the first word-line WL1 than to the second word-line WL2. The second channel pattern AP2 may be disposed closer to the second word-line WL2 than to the first word-line WL1.

Each of the first word-line WL1 and the second word-line WL2 may have a width in the second direction D2 (see FIG. 1). A width of a portion the first word-line WL1 that overlaps the channel structure AP_ST in the third direction D3 may be different from a width of a portion the first word-line WL1 that does not overlap the channel structure AP_ST. A width of a portion of the second word-line WL2 that overlaps the channel structure AP_ST in the third direction D3 may be different from a width of a portion of the second word-line WL2 that does not overlap the channel structure AP_ST.

For example, as shown in FIG. 1, each of the first word-line WL1 and the second word-line WL2 may include a first portion WLa of the word-line and a second portion WLb of the word-line. A width in the second direction D2 of the first portion WLa of the word-line may be smaller than a width in the second direction of the second portion WLb of the word-line. For example, the first portion WLa of the word-line may be disposed on the channel structure AP_ST. The first portion WLa of the word-line may be disposed on the first channel pattern AP1 and the second channel pattern AP2.

Each of the first word-line WL1 and the second word-line WL2 may include first portions WLa of the word-line and second portions WLb of the word-line alternately arranged with each other along the first direction D1. Each channel structure AP_ST may be disposed between the second portions WLb of the word-line that are adjacent to each other in the first direction D1. Each of the first active patterns AP1 may be disposed between the second portions WLb of the first word-line WL1 that are adjacent to each other in the first direction D1. Each of the second active patterns AP2 may be disposed between the second portions WLb of the second word-line WL2 that are adjacent to each other in the first direction D1.

The channel structure AP_ST is not disposed under the second portion WLb of the word-line. In some example embodiments, a vertical length of the first portion WLa of the word-line is smaller than a vertical length of the second portion WLb of the word-line.

Each of the first and second word-lines WL1 and WL2 may include a conductive material, for example, may include at least one of doped polysilicon, conductive metal nitride, conductive metal silicon nitride, metal carbonitride, conductive metal silicide, conductive metal oxide, two-dimensional material, metal, or metal alloy.

Each of the first and second word-lines WL1 and WL2 may include an upper surface WL_US and a lower surface WL_BS that are opposite to each other in the third direction D3. The lower surface WL_BS of each of the first and second word-lines WL1 and WL2 may face the liner pattern 178, the liner film 177, and the bit-line BL.

The upper surface WL_US of each of the first and second word-lines WL1 and WL2 may be flat. The lower surface WL_BS of each of the first and second word-lines WL1 and WL2 may be flat.

Based on the second surface 177_S2 of the liner film 177, a vertical level of the upper surface WL_US of each of the first and second word-lines WL1 and WL2 may be higher than that of a top level of each of the vertical portions AP_STV1 and AP_STV2 of the channel structure AP_ST. A top level of each of the channel patterns AP1 and AP2 may be the top level of each of the vertical portions AP_STV1 and AP_STV2 of the channel structure AP_ST. That is, a vertical length H3 from the second surface 177_S2 of the liner film 177 to the top level of each of the vertical portions AP_STV1 and AP_STV2 of the channel structure AP_ST may be smaller than a vertical length H4 from the second surface 177_S2 of the liner film 177 to the upper surface WL_US of each of the first and second word-lines WL1 and WL2.

A gate insulating film GOX may be disposed between the first word-line WL1 and the channel structure AP_ST and between the second word-line WL2 and the channel structure AP_ST. The gate insulating film GOX may be disposed between the first word-line WL1 and the first active pattern AP1 and between the second word-line WL2 and the second active pattern AP2. The gate insulating film GOX may extend in the first direction D1 in a parallel manner to the first word-line WL1 and the second word-line WL2.

The gate insulating film GOX may extend along the first vertical portion AP_STV1 of the channel structure AP_ST. The gate insulating film GOX may extend along the second vertical portion AP_STV2 of the channel structure AP_ST. In the semiconductor memory device according to some example embodiments, the gate insulating film GOX may not be disposed on a portion of the horizontal portion AP_STH of the channel structure AP_ST that does not overlap the first word-line WL1 and the second word-line WL2 in the third direction D3. In a cross-sectional view, the gate insulating film GOX between the first word-line WL1 and the channel structure AP_ST may be isolated from the gate insulating film GOX between the second word-line WL2 and the channel structure AP_ST.

The gate insulating film GOX may include a silicon oxide film, a silicon oxynitride film, a high dielectric constant insulating film with a higher dielectric constant than that of the silicon oxide film, or a combination thereof.

A portion of the gate insulating film GOX may protrude in the third direction D3 beyond the upper surface WL_US of each of the first and second word-lines WL1 and WL2. A portion of the gate insulating film GOX may protrude in the third direction D3 beyond the top level of each of the vertical portions AP_STV1 and AP_STV2 of the channel structure AP_ST.

A vertical length H6 from the upper surface of the liner pattern 178 to a top level GOX_UUS of the gate insulating film GOX may be larger than the vertical length H3 from the upper surface of the liner pattern 178 to the top level of each of the vertical portions AP_STV1 and AP_STV2 of the channel structure AP_ST. The vertical length H6 from the upper surface of the liner pattern 178 to the top level GOX_UUS of the gate insulating film GOX may be larger than the vertical length H4 from the upper surface of the liner pattern 178 to the upper surface WL_US of each of the first and second word-lines WL1 and WL2.

A gate isolation pattern GSS may be disposed on the liner film 177 and the cell lower insulating film 171. The gate isolation pattern GSS may be disposed within the channel trench CH_T. The gate isolation pattern GSS may be disposed on the channel structure AP_ST, the first word-line WL1, and the second word-line WL2.

In the semiconductor memory device according to some example embodiments, the gate isolation pattern GSS may contact the channel structure AP_ST. The gate isolation pattern GSS may be disposed on the connection channel pattern AP_CP. The gate isolation pattern GSS may contact the horizontal portion AP_STH of the channel structure AP_ST. The gate isolation pattern GSS may be spaced apart from the bit line BL in the third direction D3. The gate isolation pattern GSS may be spaced apart from the liner film 177 and the liner pattern 178 in the third direction D3.

The gate isolation pattern GSS may be disposed between the first word-line WL1 and the second word-line WL2 adjacent to each other in the second direction D2. The first word-line WL1 and the second word-line WL2 may be isolated from each other via the gate isolation pattern GSS. The gate isolation pattern GSS may extend in the first direction D1 and between the first word-line WL1 and the second word-line WL2.

The first word-line WL1 may be disposed between the gate isolation pattern GSS and the channel structure AP_ST. The second word-line WL2 may be disposed between the gate isolation pattern GSS and the channel structure AP_ST. The first word-line WL1 may be disposed between the gate isolation pattern GSS and the first channel pattern AP1. The second word-line WL2 may be disposed between the gate isolation pattern GSS and the second channel pattern AP2.

The gate isolation pattern GSS may include a horizontal portion and a protrusion. The protrusion of the gate isolation pattern GSS may protrude in the third direction D3 from the horizontal portion of the gate isolation pattern GSS toward the liner film 177. The protrusion of the gate isolation pattern GSS may be closer to the liner film 177 than the horizontal portion of the gate isolation pattern GSS may be. The horizontal portion of the gate isolation pattern GSS may be disposed on the upper surface WL_US of each of the first and second word-lines WL1 and WL2. In a cross-sectional view, the gate isolation pattern GSS may have a “T” shape.

The gate isolation pattern GSS may include a gate isolation liner 151, and a gate isolation filling film 153. The gate isolation liner 151 may extend along the upper surface WL_US of each of the first and second word-lines WL1 and WL2 and the outer sidewall of each of the first and second word-lines WL1 and WL2. The gate isolation liner 151 may extend along the horizontal portion AP_STH of the channel structure AP_ST. The gate isolation liner 151 may contact the connection channel pattern AP_CP. The gate isolation liner 151 may extend along a portion of the gate insulating film GOX protruding upwardly beyond the upper surface WL_US of each of the first and second word-lines WL1 and WL2. In some example embodiments, the gate isolation liner 151 may not extend along the portion of the gate insulating film GOX protruding beyond the upper surface WL_US of each of the first and second word-lines WL1 and WL2.

The gate isolation filling film 153 may be disposed on the gate isolation liner 151. The gate isolation filling film 153 may contact the gate isolation liner 151. In a cross-sectional view, the gate isolation filling film 153 may have a “T” shape. Each of the gate isolation liner 151 and the gate isolation filling film 153 may be made of or may include an insulating material. In some example embodiments, the gate isolation pattern GSS may be embodied as a single film.

Based on the upper surface of the bit-line BL, an upper surface GSS_US of the gate isolation pattern GSS may be located at the same vertical level as that of the upper surface of the protruding insulating pattern 175. However, example embodiments of the present disclosure are not limited thereto.

The vertical length H5 from the upper surface of the liner pattern 178 to the upper surface GSS_US of the gate isolation pattern GSS may be larger than the vertical length H3 from the upper surface of the liner pattern 178 to the top level of the vertical portions AP_STV1 and AP_STV2 of the channel structure AP_ST. The vertical length H5 from the upper surface of the liner pattern 178 to the upper surface GSS_US of the gate isolation pattern GSS may be larger than the vertical length H4 from the upper surface of the liner pattern 178 to the upper surface WL_US of each of the word-lines WL1 and WL2.

The vertical length H5 from the upper surface of the liner pattern 178 to the upper surface GSS_US of the gate isolation pattern GSS is shown to be equal to the vertical length H6 from the upper surface of the liner pattern 178 to the top level GOX_UUS of the gate insulating film GOX. However, embodiments of the present disclosure are not limited thereto.

The landing pads LP may be disposed on the channel structure AP_ST. The landing pads LP may be connected to the first vertical portion AP_STV1 of the channel structure AP_ST and the second vertical portion AP_STV2 of the channel structure AP_ST.

The landing pads LP may be disposed on the first channel pattern AP1 and the second channel pattern AP2. The landing pads LP may be connected to the first channel pattern AP1 and the second channel pattern AP2.

In a plan view, each of the landing pads LPs may have various shapes such as circular, oval, rectangular, square, diamond, and hexagonal shapes.

The landing pad LP may include a horizontal portion LP_H and a protrusion LP_P. The horizontal portion LP_H of the landing pad LP may be disposed on the upper surface of the protruding insulating pattern 175 and the upper surface GSS_US of the gate isolation pattern GSS. The protrusion LP_P of the landing pad LP may protrude in the third direction D3 from the horizontal portion LP_H of the landing pad LP toward the liner film 177.

Based on the upper surface of the bit-line BL, a vertical level of a bottom surface of the landing pad LP may be lower than that of the upper surface GSS_US of the gate isolation pattern GSS. In other words, the protrusion LP_P of the landing pad LP may be disposed between the protruding insulating pattern 175 and the gate isolation pattern GSS. A vertical length from the upper surface of the bit-line BL to the bottom surface of the landing pad LP may be smaller than the vertical length from the upper surface of the bit-line BL to the top level GOX_UUS of the gate insulating film GOX.

Pad isolation insulating patterns 235 may be disposed between the landing pads LP.

In the plan view, the landing pads LP may be arranged in a matrix form along the first direction D1 and the second direction D2. The upper surface of the landing pad LP may be coplanar with the upper surface of the pad isolation insulating pattern 235. However, example embodiments of the present disclosure are not limited thereto.

The landing pad LP includes a conductive material. The landing pad LP may include at least one of, for example, doped polysilicon, conductive metal nitride, conductive metal silicon nitride, metal carbonitride, conductive metal silicide, conductive metal oxide, two-dimensional material, metal, or metal alloy.

The data storage patterns DSP may be disposed on the landing pads LPs, respectively. The data storage patterns DSP may be connected (e.g., electrically connected) to the first vertical portion AP_STV1 of the channel structure AP_ST and the second vertical portion AP_STV2 of the channel structure AP_ST. The data storage patterns DSP may be connected to the first and second channel patterns AP1 and AP2, respectively.

The data storage patterns DSP may be arranged in a matrix form along the first direction D1 and the second direction D2, as shown in FIG. 1. The data storage patterns DSP may entirely overlap or partially overlap the landing pads LP in the third direction D3, respectively. The data storage pattern DSP may contact an entirety or a portion of the upper surface of each of the landing pads LP.

In one example, the data storage pattern DSP may be a capacitor. The first channel pattern AP1 may be connected to a first capacitor. The second channel pattern AP2 may be connected to a second capacitor.

The data storage pattern DSP may include a capacitor dielectric film 253 interposed between a storage electrode 251 and a plate electrode 255. In this case, the storage electrode 251 may contact the landing pad LP. In the plan view, the storage electrode 251 may have various shapes such as circular, oval, rectangular, square, diamond, and hexagonal shapes. The data storage pattern DSP may entirely overlap or partially overlap the landing pad LP. The data storage pattern DSP may contact an entirety or a portion of the upper surface of each of the landing pads LP. The storage electrodes 251 may extend through a cell upper etch stop film 247. The cell upper etch stop film 247 may be made of or may include an insulating material.

In some example embodiments, each of the data storage patterns DSP may be embodied as a variable resistance pattern that may be switched to between two resistance states under an electrical pulse applied to a memory element. For example, each of the data storage patterns DSP may include a phase-change material having a crystal state varying depending on an amount of current, perovskite compounds, transition metal oxides, magnetic materials, ferromagnetic materials, or antiferromagnetic materials.

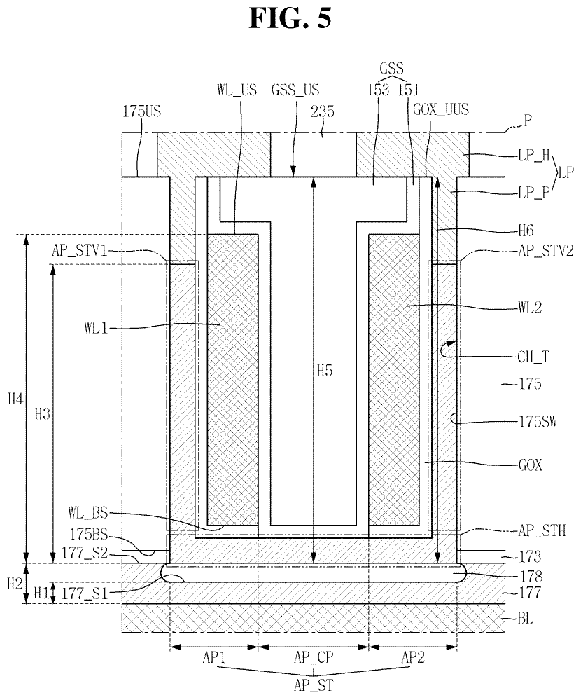

FIGS. 5 to 9 are diagrams for illustrating a semiconductor memory device according to some example embodiments of the present disclosure. FIGS. 5 to 9 are enlarged views of a P portion of FIG. 2. For convenience of description, contents duplicate with what has been described above in FIGS. 1 to 4 are briefly described or the descriptions thereof are omitted.

Referring to FIG. 5, the liner pattern 178 may have curved both opposing ends. Each of the both opposing ends of the liner pattern 178 may protrude in the second direction D2 beyond the channel structure AP_ST. For example, each of the both opposing ends of the liner pattern 178 may protrude in the second direction D2 beyond a contact surface between the protruding insulating pattern 175 and the vertical portion AP_STV1 and AP_STV2 of the channel structure AP_ST. The protruding insulating pattern 175 may include the upper surface 175US and the lower surface 175BS that are opposite to each other. The upper surface 175US of the protruding insulating pattern 175 may contact the landing pad LP and the pad isolation insulating pattern 235. The lower surface 175BS of the protruding insulating pattern 175 may contact the cell lower etch stop film 173. Although not shown, when there is no cell lower etch stop film 173, the lower surface 175BS of the protruding insulating pattern 175 may contact the liner film 177. At least a portion of the bottom surface 175BS of the protruding insulating pattern 175 may not overlap the liner pattern 178 in the third direction D3. That is, since each of the both opposing ends of the liner pattern 178 protrude in the second direction D2 beyond the channel structure AP_ST, the portion of the bottom surface 175BS of the protruding insulating pattern 175 may not overlap the liner pattern 178. The remainder of the bottom surface 175BS of the protruding insulating pattern 175 may overlap the liner pattern 178 in the third direction D3.

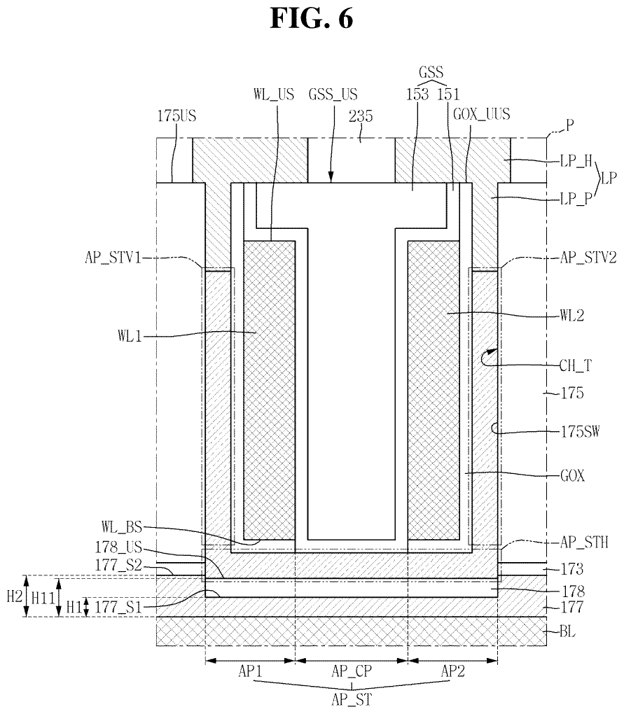

Referring to FIG. 6, the upper surface 178_US of the liner pattern 178 and the second surface 177_S2 of the liner film 177 may not be coplanar with each other. A vertical length H11 from the bit-line BL to the upper surface 178_US of the liner pattern 178 may be greater than the vertical length H1 from the bit-line BL to the first surface 177_S1 of the liner film 177. Based on the bit-line BL, a vertical level of the upper surface 178_US of the liner pattern 178 may be lower than that of the second surface 177_S2 of the liner film 177. That is, a vertical length H11 from the bit-line BL to the upper surface 178_US of the liner pattern 178 may be smaller than the vertical length H2 from the bit-line BL to the second surface 177_S2 of the liner film 177.

The lower surface of the cell lower etch stop film 173 in contact with the liner film 177 may be positioned at a higher level than the lower surface of the horizontal portion AP_STH of the channel structure AP_ST in contact with the liner pattern 178.

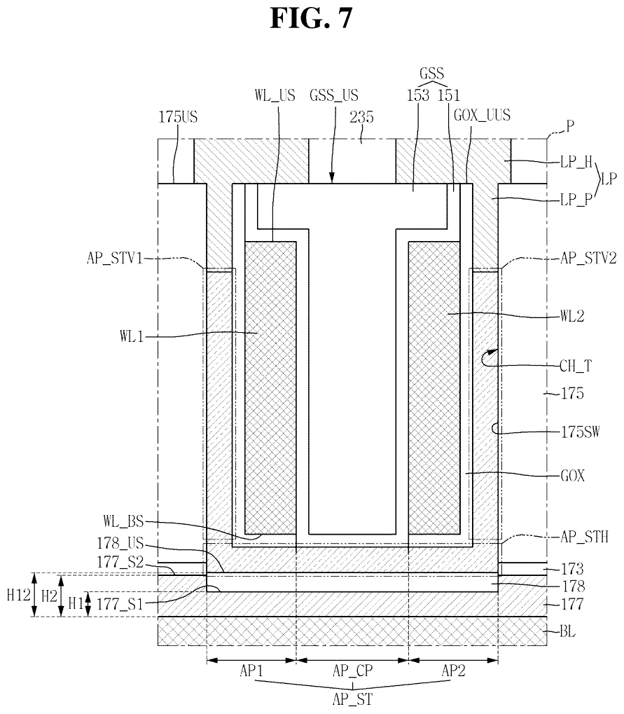

Referring to FIG. 7, the upper surface 178_US of the liner pattern 178 and the second surface 177_S2 of the liner film 177 may not be coplanar with each other. A vertical length H12 from the bit-line BL to the upper surface 178_US of the liner pattern 178 may be greater than the vertical length H1 from the bit-line BL to the first surface 177_S1 of the liner film 177. Based on the bit-line BL, the upper surface 178_US of the liner pattern 178 may be positioned at a higher level than the second surface 177_S2 of the liner film 177. That is, the vertical length H12 from the bit-line BL to the upper surface 178_US of the liner pattern 178 may be larger than the vertical length H2 from the bit-line BL to the second surface 177_S2 of the liner film 177.

The lower surface of the cell lower etch stop film 173 in contact with the liner film 177 may be positioned at a lower level than that of the lower surface of the horizontal portion AP_STH of the channel structure AP_ST in contact with the liner pattern 178.

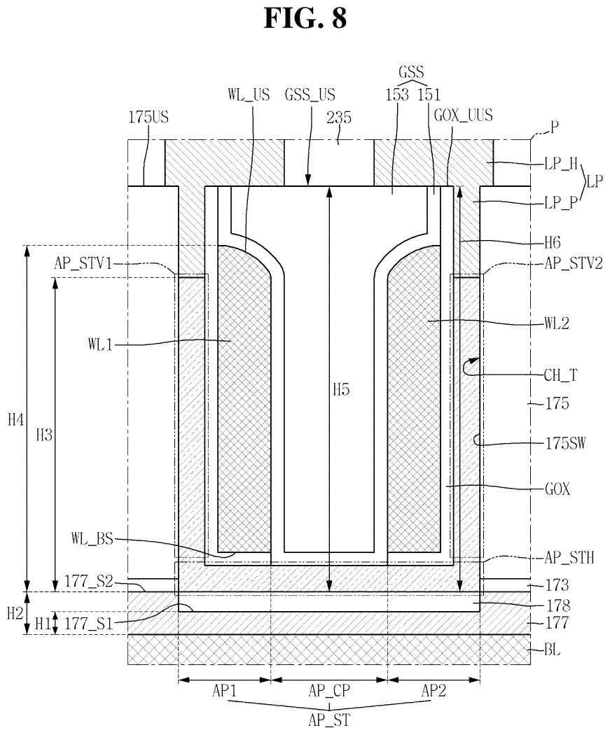

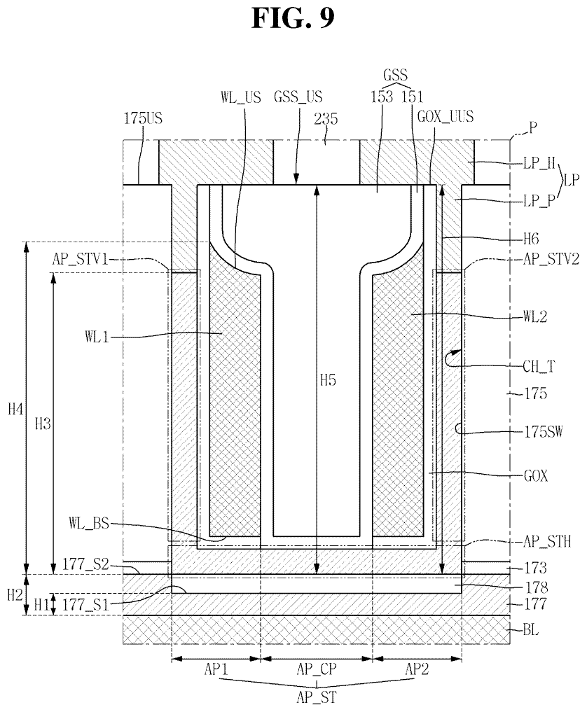

Referring to FIG. 8, the upper surface WL_US of the first and second word-lines WL1 and WL2 may be convexly rounded. Referring to FIG. 9, the upper surface WL_US of the first and second word-lines WL1 and WL2 may be concavely rounded.

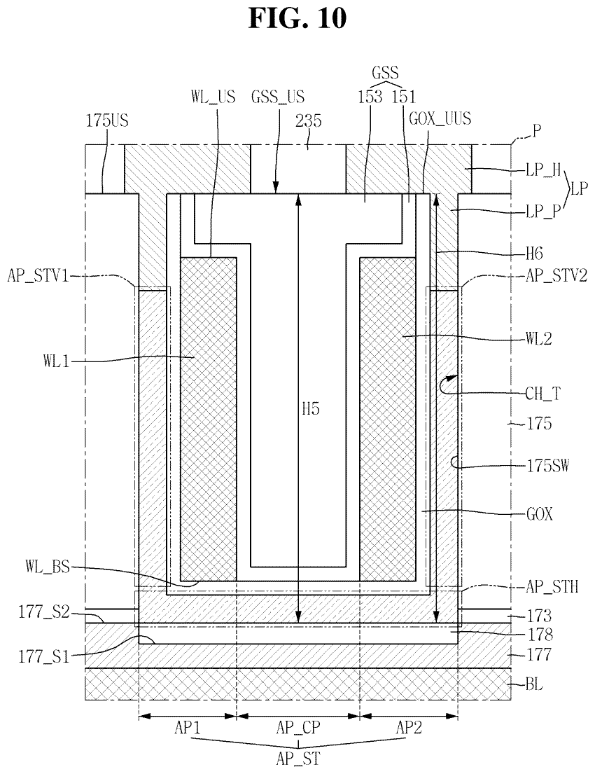

FIG. 10 is a diagram for illustrating a semiconductor memory device according to an example embodiment of the present disclosure. For convenience of description, contents duplicate with what has been described above in FIGS. 1 to 4 are briefly described or the descriptions thereof are omitted.

Referring to FIG. 10, in a semiconductor memory device according to an example embodiment, the gate isolation pattern GSS does not contact the channel structure AP_ST.

A portion of the gate insulating film GOX may be disposed between the gate isolation pattern GSS and the channel structure AP_ST. In the cross-sectional view, a portion of the gate insulating film GOX between the first word-line WL1 and the channel structure AP_ST may be connected to a portion of the gate insulating film GOX between the second word-line WL2 and the channel structure AP_ST.

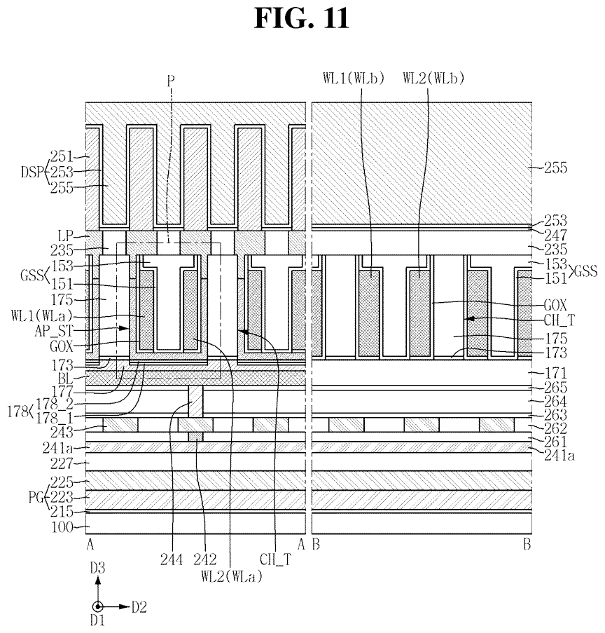

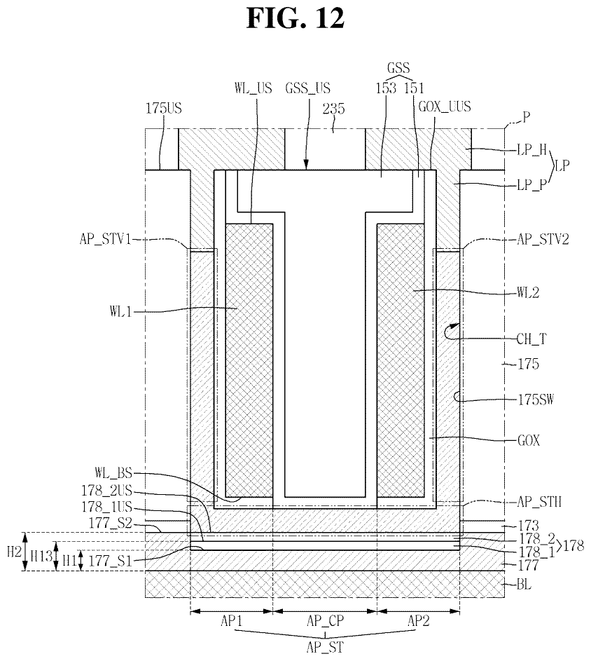

FIG. 11 and FIG. 12 are diagrams for illustrating a semiconductor memory device according to an example embodiment of the present disclosure. For convenience of description, contents duplicate with what has been described above in FIGS. 1 to 4 are briefly described or the descriptions thereof are omitted.

Referring to FIG. 11 and FIG. 12, the liner film 177 may extend along the upper surface of the bit-line BL. The liner pattern 178 may be disposed on the liner film 177. The liner pattern 178 may include a first liner pattern 178_1 and a second liner pattern 178_2. The first liner pattern 178_1 may be disposed on the first surface 177_S1 of the liner film 177. The second liner pattern 178_2 may be disposed on the upper surface 178_1US of the first liner pattern 178_1.

The upper surface 178_2US of the second liner pattern 178_2 may be coplanar with the second surface 177_S2 of the liner film 177. However, example embodiments of the present disclosure are not limited thereto.

A vertical length H13 from the upper surface of the bit-line BL to the upper surface 178_1US of the first liner pattern 178_1 may be larger than the vertical length H1 from the upper surface of the bit-line BL to the first surface 177_S1 of the first liner film 177. The vertical length H13 from the upper surface of the bit-line BL to the upper surface 178_1US of the first liner pattern 178_1 may be smaller than the vertical length H2 from the upper surface of the bit-line BL to the second surface 177_S2 of the first liner film 177.

The first liner pattern 178_1 may include titanium oxide seeded with silicon (Si). In this case, the first liner pattern 178_1 may have oxidation resistance. In other words, the first liner pattern 178_1 may be mitigated or prevented from being oxidized toward the liner film 177. The second liner pattern 178_2 may include titanium oxide doped with niobium (Nb). In this case, the second liner pattern 178_2 may have surplus electrons, so that electrical conductivity thereof may be improved.

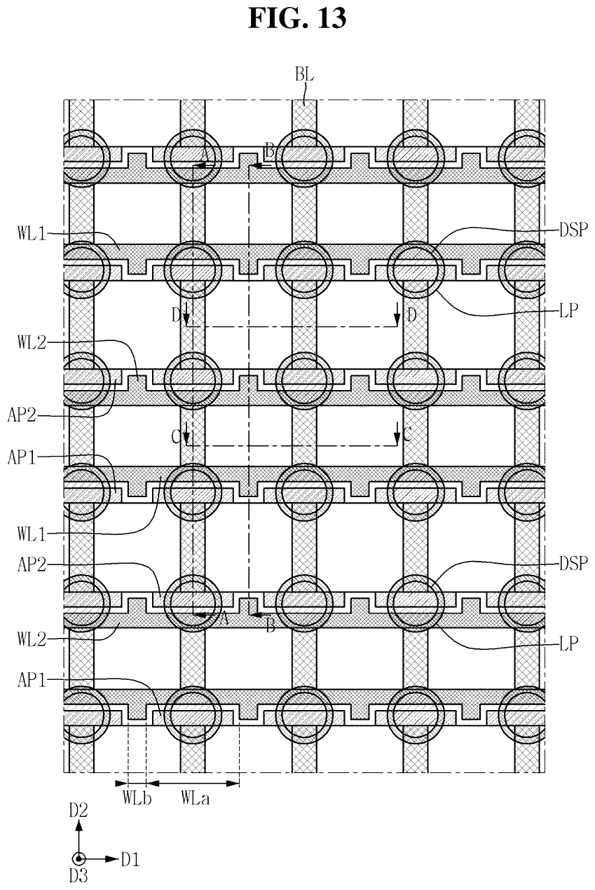

FIGS. 13 to 16 are diagrams for illustrating semiconductor memory devices according to an example embodiment of the present disclosure. For convenience of description, contents duplicate with what has been described above in FIGS. 1 to 4 are briefly described or the descriptions thereof are omitted.

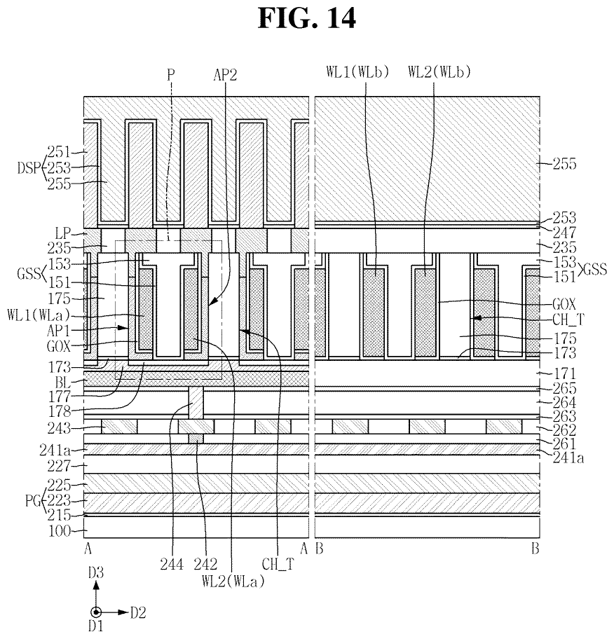

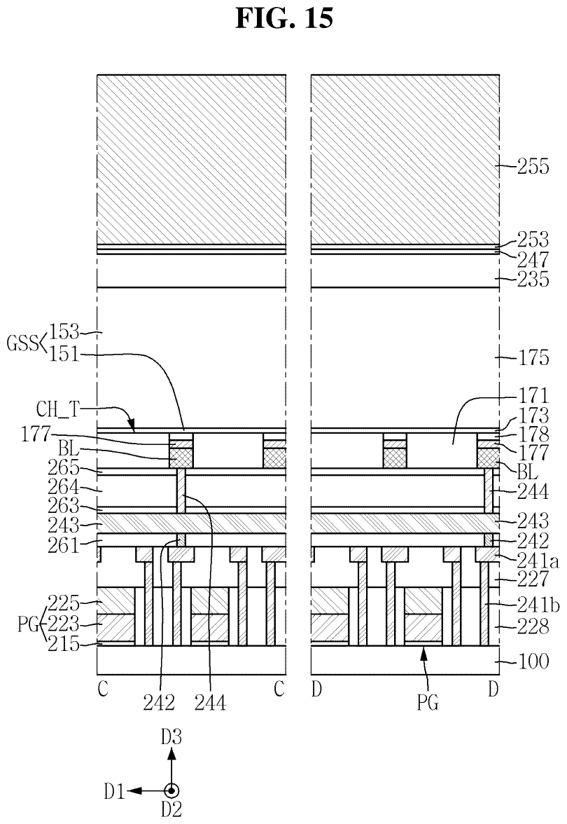

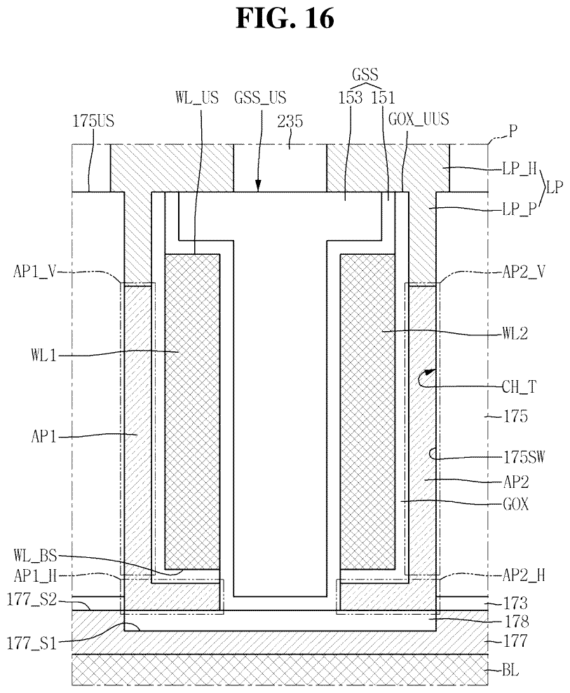

For reference, FIG. 13 is a layout diagram for illustrating a semiconductor memory device according to an example embodiment. FIG. 14 is a cross-sectional view cut along lines A-A and B-B in FIG. 13. FIG. 15 is a cross-sectional view cut along lines C-C and D-D in FIG. 13. FIG. 16 is an enlarged view of a P portion of FIG. 14.

Referring to FIGS. 13 to 16, in the semiconductor memory device according to an example embodiment, the first channel pattern AP1 and the second channel pattern AP2 spaced apart from each other in the second direction D2 are not connected to each other in the channel trench CH_T.

Each of the first channel pattern AP1 and the second channel pattern AP2 may include metal oxide.

The first channel pattern AP1 may include a horizontal portion AP1_H extending along the upper surface of the liner pattern 178 and a vertical portion AP1_V extending along the sidewall 175SW of the protruding insulating pattern 175. The vertical portion AP1_V of the first channel pattern AP1 may protrude in the third direction D3 from the horizontal portion AP1_H of the first channel pattern AP1.

The second channel pattern AP2 may include a horizontal portion AP2_H extending along the upper surface of the liner pattern 178 and a vertical portion AP2_V extending along the sidewall 175SW of the protruding insulating pattern 175. The vertical portion AP2_V of the second channel pattern AP2 may protrude from the horizontal portion AP2_H of the second channel pattern AP2 in the third direction D3.

The gate isolation pattern GSS may be in contact with the liner pattern 178. The horizontal portion AP2_H of the second channel pattern AP2 and the horizontal portion AP1_H of the first channel pattern AP1 may be spatially isolated from each other via the gate isolation pattern GSS. The gate isolation liner 151 may contact the liner pattern 178.

Conventionally, when the channel structure AP_ST including the metal oxide is disposed on the bit-line BL, a thick oxide film may be formed at an interface between the bit-line BL and the channel structure AP_ST. In this case, a contact resistance between the bit-line BL and the channel structure AP_ST may be increased, making it difficult to secure on current (Ion).

However, the semiconductor memory device according to some example embodiments of the present disclosure may include the liner film 177 disposed on the bit-line BL and extending along the upper surface of the bit-line BL, and the liner pattern 178 disposed on the liner film 177. The bit-line BL may include first metal. The liner film 177 may include second metal that is different from the first metal. The liner pattern 178 may include oxide of the second metal. For example, the liner film 177 may include at least one of TiN (titanium nitride), Zn, In, or Ni. When the liner film 177 includes titanium nitride, the liner pattern 178 may include titanium oxide seeded with silicon and/or titanium oxide doped with niobium. When the liner film 177 includes titanium nitride, an energy barrier height at an interface between the bit-line BL and the channel structure AP_ST may be reduced. Additionally, when the liner film 177 includes titanium nitride, a thickness of the oxide film between the liner film 177 and the channel structure AP_ST may be reduced, so that the on current may increase. When the liner pattern 178 includes titanium oxide seeded with silicon, oxidation resistance thereof may be improved, thereby mitigating preventing the liner pattern 178 from being oxidized toward the liner film 177, thereby mitigating or preventing the oxide film from being thick. When the liner pattern 178 is doped with niobium, the liner pattern 178 may have excess electrons as niobium acts as an n-type dopant. Therefore, when the liner pattern 178 includes titanium oxide doped with niobium, electrical conductivity thereof may be improved.

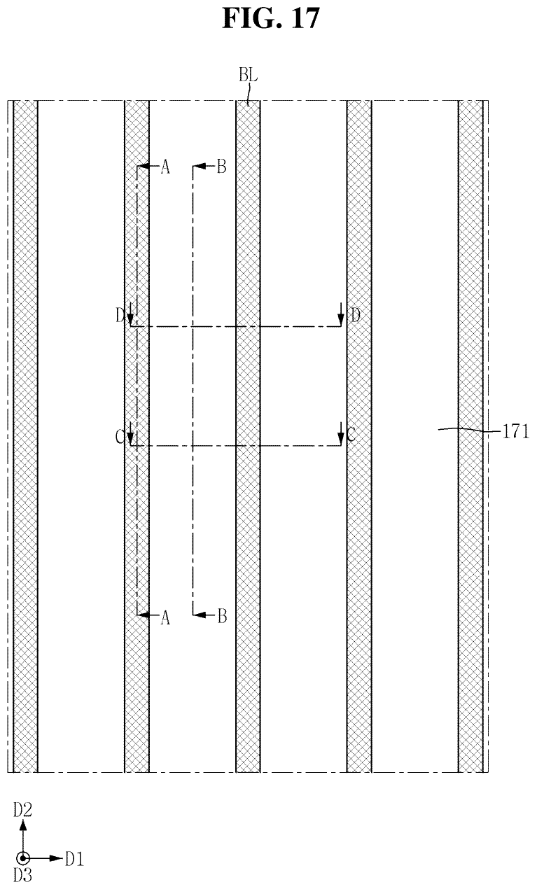

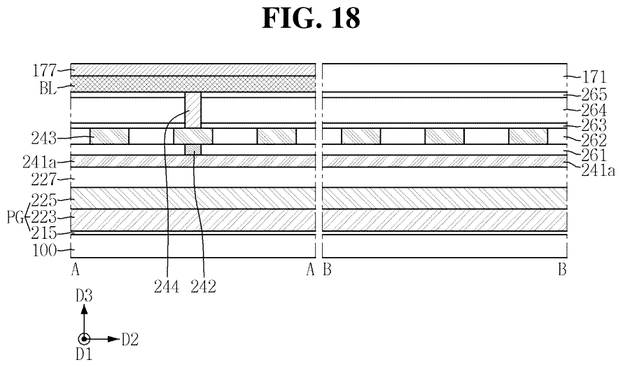

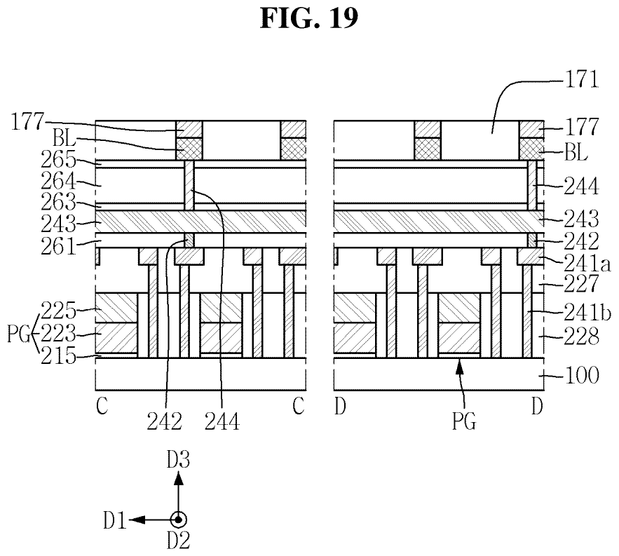

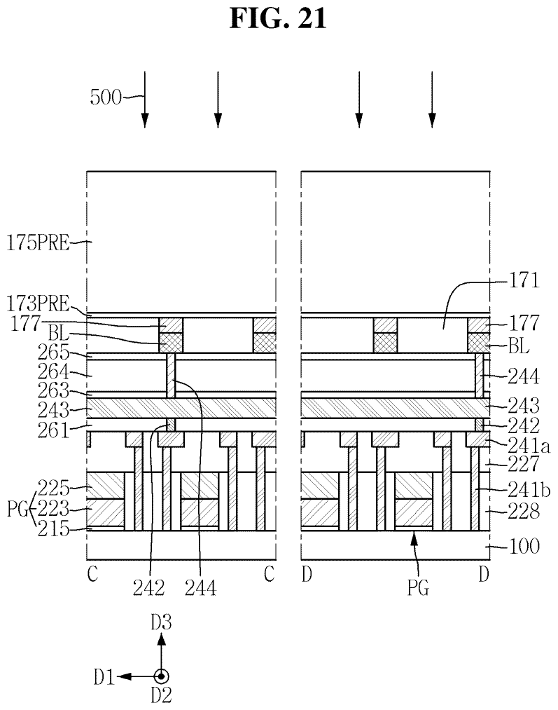

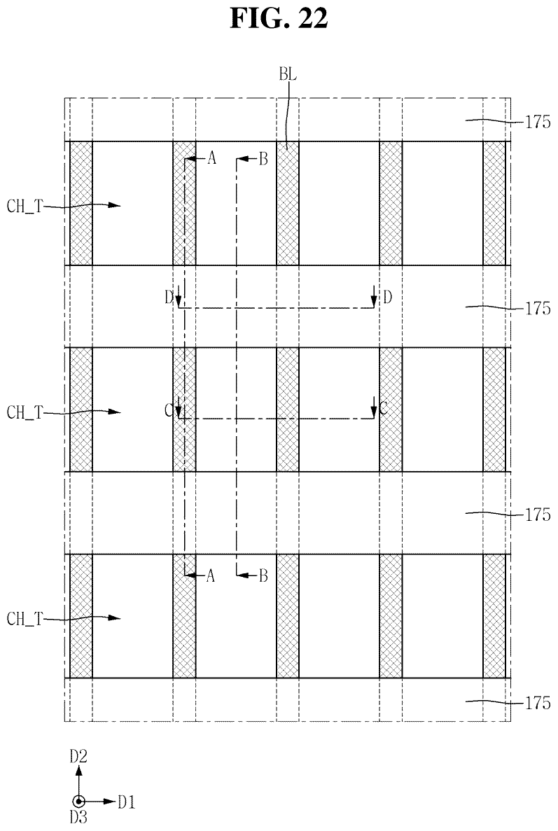

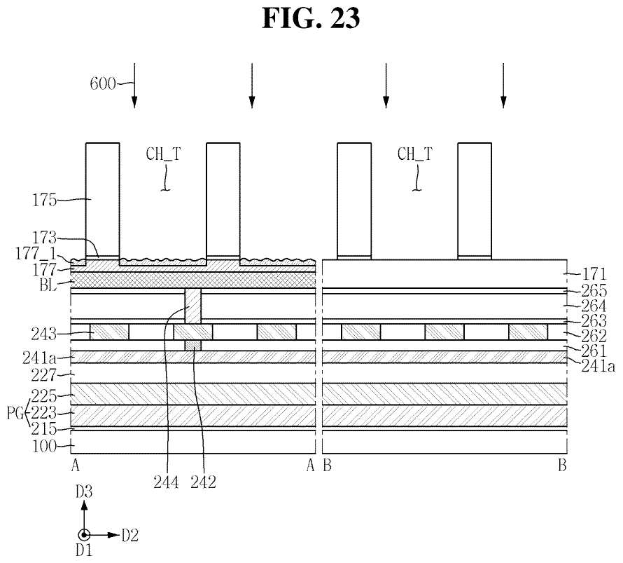

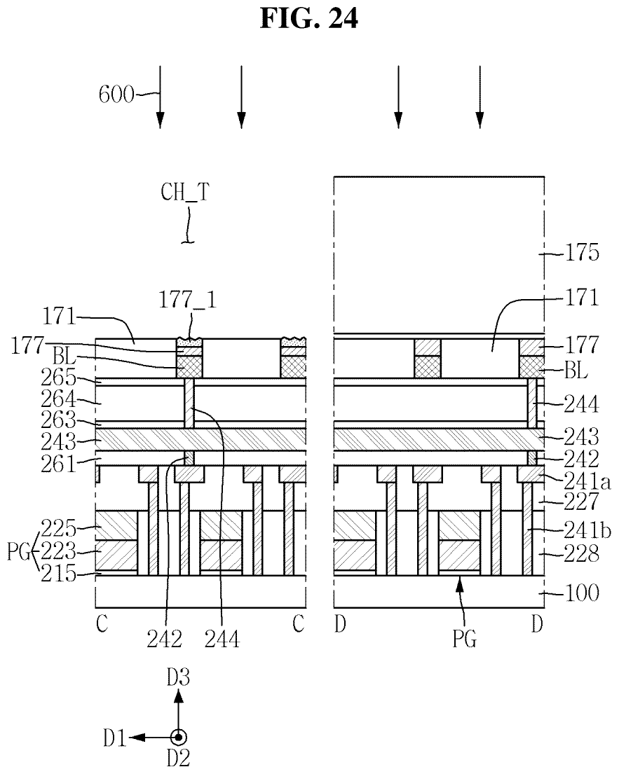

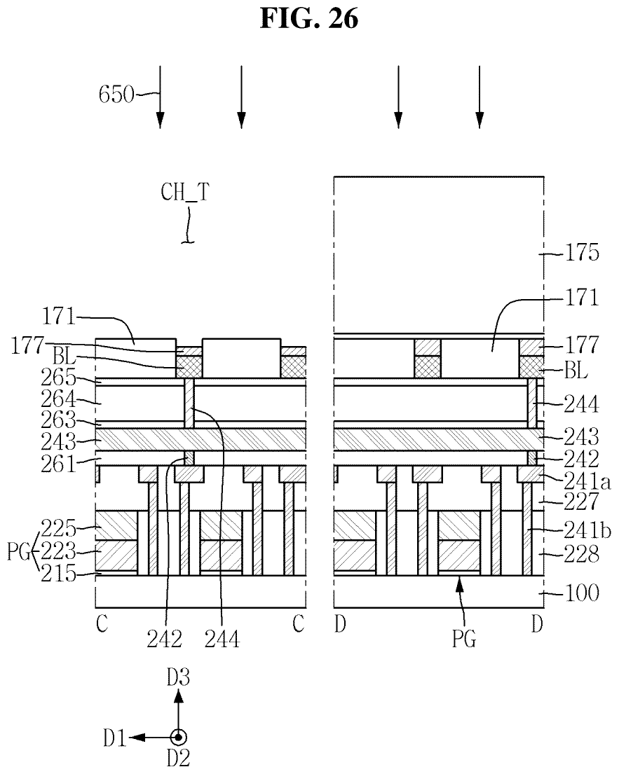

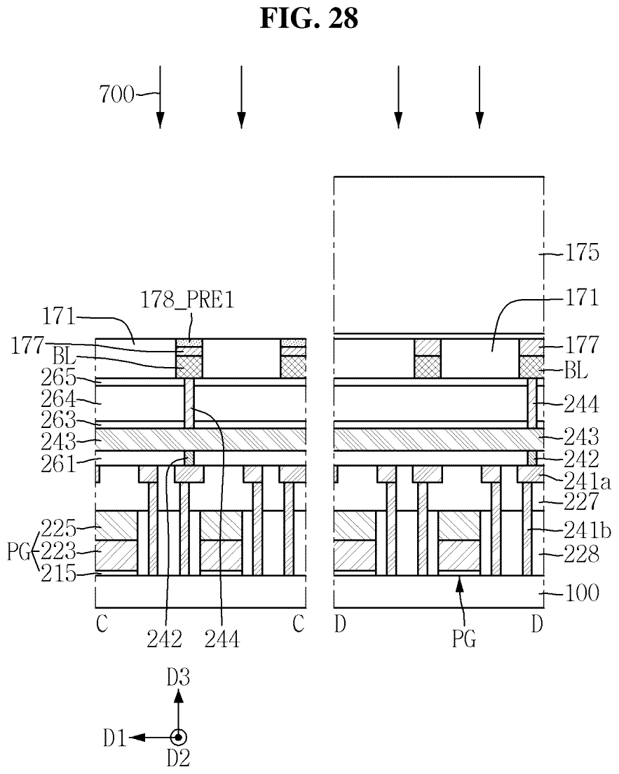

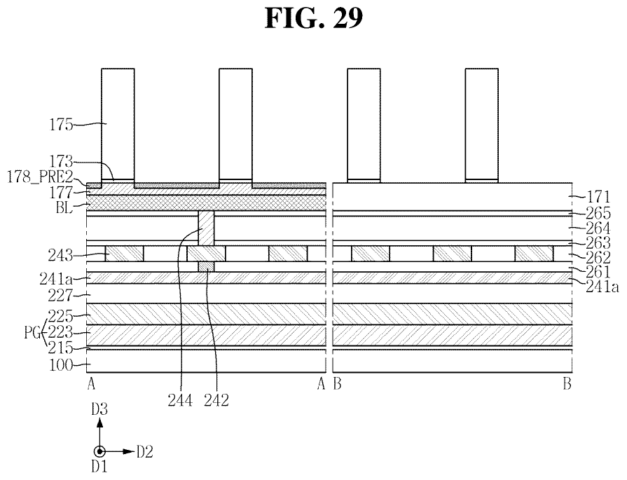

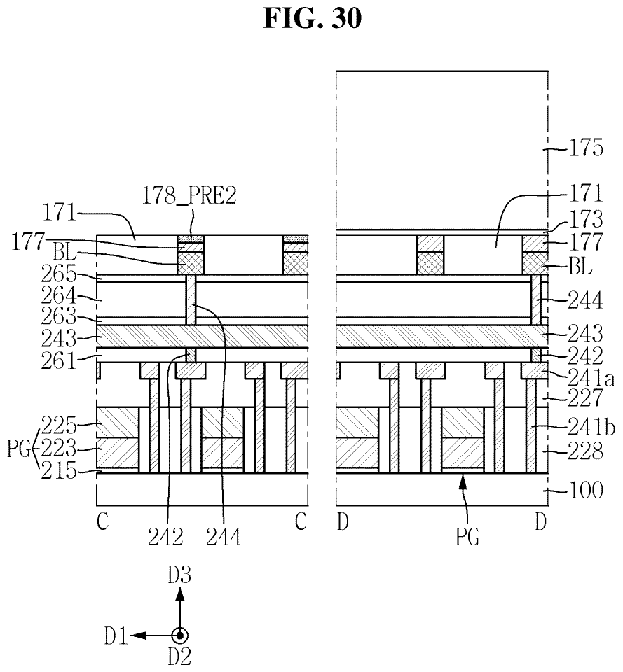

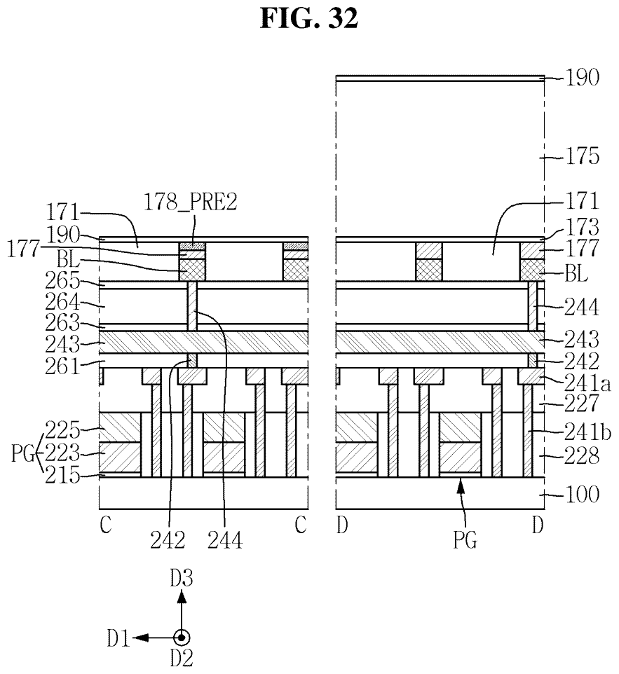

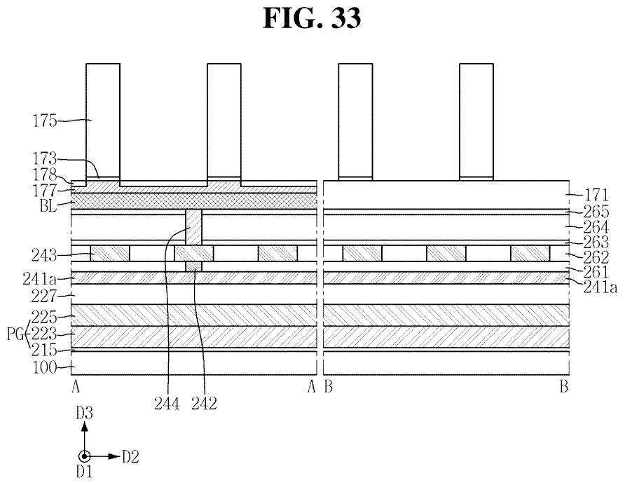

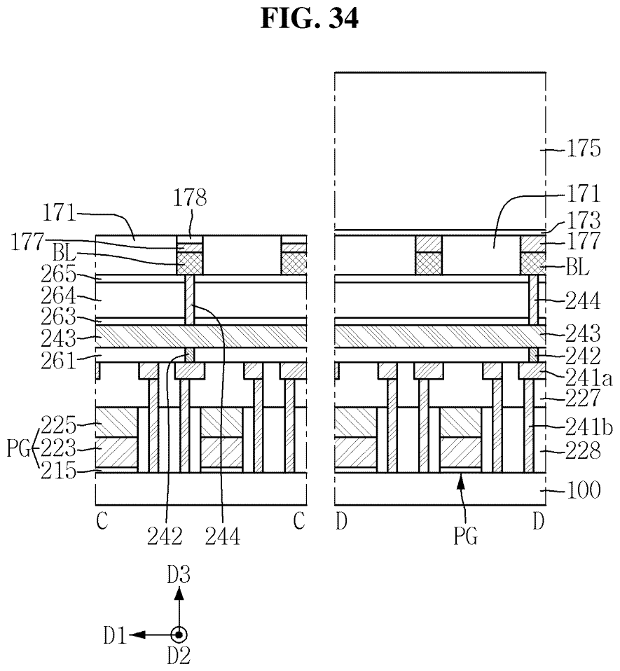

FIGS. 17 to 42 are diagrams for illustrating a semiconductor memory device manufacturing method according to an example embodiment of the present disclosure. For convenience of description, contents duplicate with what has been described above in FIGS. 1 to 16 are briefly described or the descriptions thereof are omitted.

Referring to FIGS. 17 to 19, the peripheral gate structure PG may be formed on the substrate 100.

The first peripheral wiring line 241a and the peripheral contact plug 241b may be formed on the substrate 100.

The peripheral upper insulating film 261, 262, 263, 264, and 265 may be sequentially formed on the first peripheral wiring line 241a and the peripheral contact plug 241b. The second peripheral wiring line 243, the peripheral via plug 242, and the cell connection plug 244 may be formed within the peripheral upper insulating film 261, 262, 263, 264, and 265.

Subsequently, the bit-line BL and the liner film 177 may be formed on the fifth peripheral upper insulating film 265. The bit-line BL may extend in an elongated manner in the second direction D2 and may be disposed on the substrate 100. The liner film 177 may extend in an elongated manner in the second direction D2 and along the upper surface of the bit-line BL. The cell lower insulating film 171 may be formed on the fifth peripheral upper insulating film 265. The cell lower insulating film 171 may not cover the upper surface of the liner film 177.

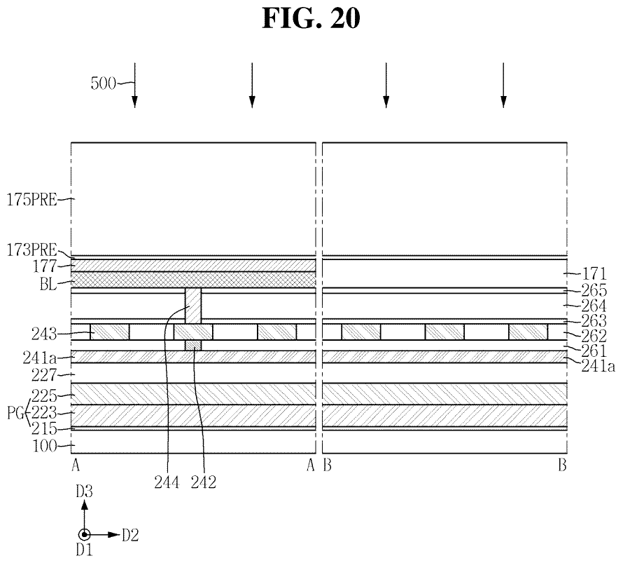

Referring to FIG. 20 to FIG. 24, a pre-cell lower etch stop film 173PRE and a pre-protruding insulating pattern 175PRE may be formed on the liner film 177 and the cell lower insulating film 171.

Subsequently, a first etching process 500 may be performed to form the cell lower etch stop film 173 and the protruding insulating pattern 175.

When the first etching process 500 is performed, a top portion of the liner film 177 may be damaged. Therefore, a first damaged layer 177_1 may be formed at the top of the liner film 177. The first damaged layer 177_1 may include a native oxide film.

The protruding insulating pattern 175 may include a plurality of channel trenches CH_T extending in the first direction D1. The channel trench CH_T may intersect the liner film 177. The channel trench CH_T may expose the liner film 177. For example, the channel trench CH_T may expose the first damaged layer 177_1.

Subsequently, a first surface treatment 600 may be performed on the first damaged layer 177_1. The first surface treatment 600 may be NH₃ plasma treatment. When the first surface treatment 600 has been performed on the first damaged layer 177_1, the first damaged layer 177_1 may be removed. The first damaged layer 177_1 including the native oxide film may be uniformly reduced under the first surface treatment 600.

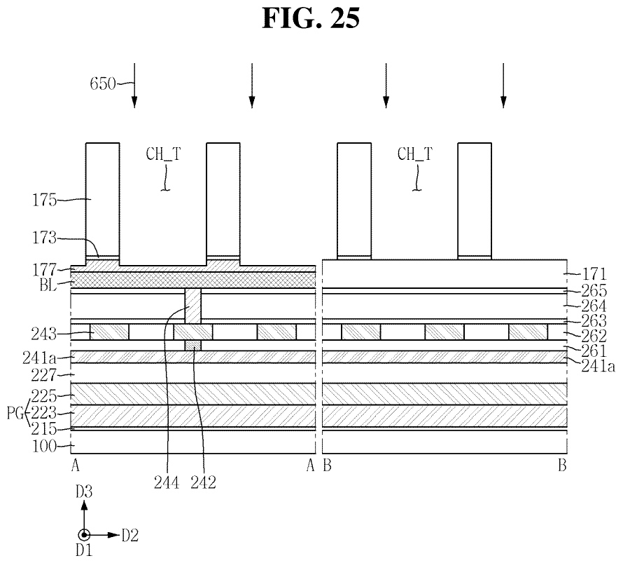

Referring to FIGS. 25 to 28, a second surface treatment 650 may then be performed on the liner film 177. The second surface treatment 650 may be O₃ plasma treatment. After the second surface treatment 650 has been performed on the liner film 177 exposed through the channel trench CH_T, a first pre-liner pattern 178_PRE1 may be formed. The first pre-liner pattern 178_PRE1 may include a homogeneous oxide film.

When the first surface treatment 600 and the second surface treatment 650 has been performed, the homogeneous oxide film may be formed. When the protruding insulating pattern 175 is formed through the first etching process 500, a portion of the liner film 177 may be damaged such that a non-uniform natural oxide film may be formed. The non-uniform native oxide film may result in irregular contact resistance distribution. However, when the first damaged layer 177_1 is removed through the first surface treatment 600 and the first pre-liner pattern 178_PRE1 is formed through the second surface treatment 650, the homogeneous oxide film may be formed. The homogeneous oxide film may improve contact resistance distribution.

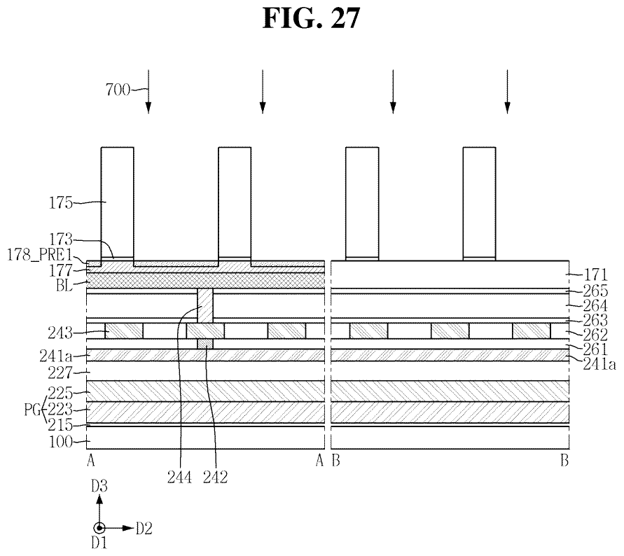

Referring to FIGS. 27 to 30, Si may be seeded into the first pre-liner pattern 178_PRE1 through a Si seeding process 700. Si may be seeded into the first pre-liner pattern 178_PRE1 to form a second pre-liner pattern 178_PRE2. The second pre-liner pattern 178_PRE2 may have oxidation resistance. In other words, the second pre-liner pattern 178_PRE2 may be blocked or prevented from being oxidized toward the liner film 177.

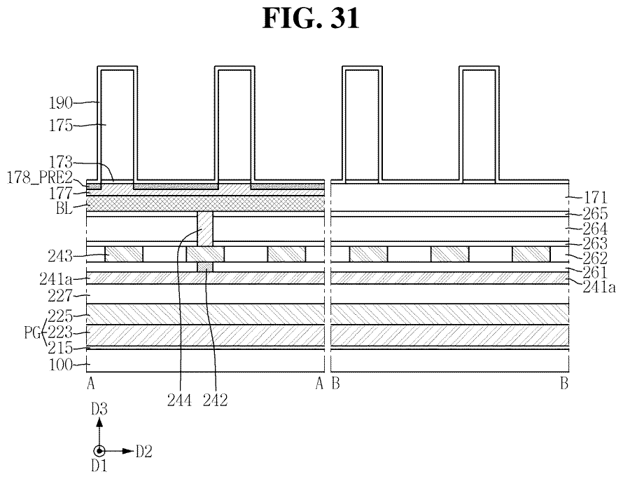

Referring to FIGS. 31 to 34, a doped layer 190 may be formed on the second pre-liner pattern 178_PRE2, the protruding insulating pattern 175, and the cell lower insulating film 171.

The doped layer 190 may be formed using an atomic layer deposition (ALD) scheme. The doped layer 190 may contain an n-type dopant. The doped layer 190 may be made of one of Nb₂O₅, Nd₂O₃, In₂O₃, Al₂O₃, or Co₃O₄.

After forming the doped layer 190, heat treatment (annealing) may be performed so that the second pre-liner pattern 178_PRE2 may be doped with the n-type dopant. The second pre-liner pattern 178_PRE2 may be doped with the n-type dopant to form the liner pattern 178. Afterwards, the doped layer 190 may be removed. Because the liner pattern 178 is doped with the n-type dopant, electrical conductivity thereof may be improved.

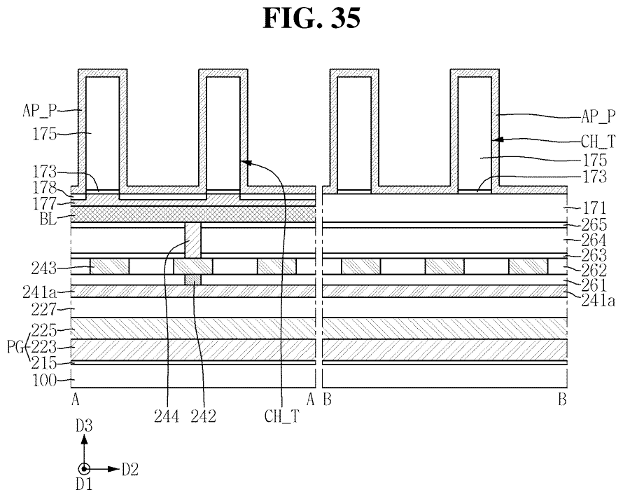

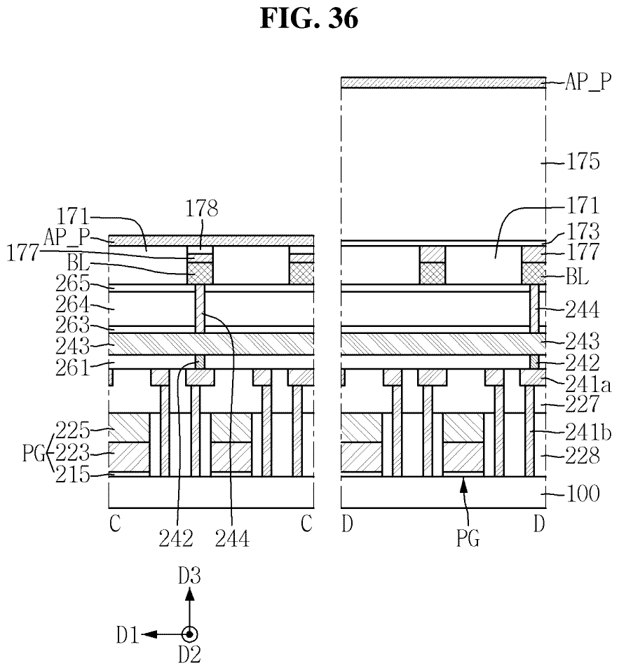

Referring to FIG. 35 and FIG. 36, a pre-channel structure AP_P may be formed along the sidewall and the bottom surface of the channel trench CH_T. The pre-channel structure AP_P may be formed on the liner pattern 178. The pre-channel structure AP_P may be formed along the sidewall and the upper surface of the protruding insulating pattern 175. The liner pattern 178 may be disposed between the pre-channel structure AP_P and the liner film 177.

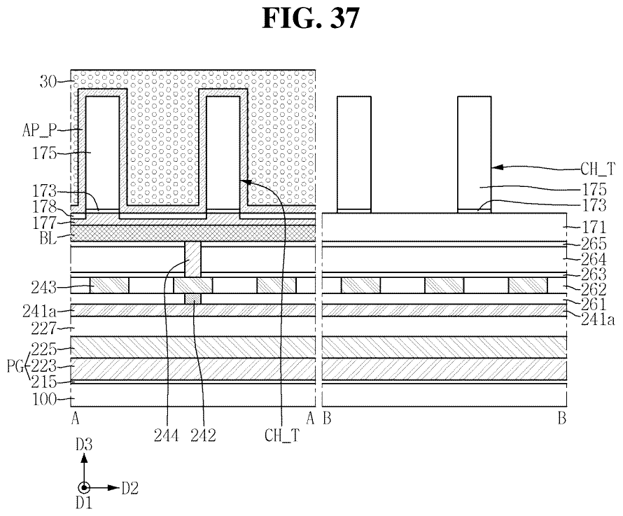

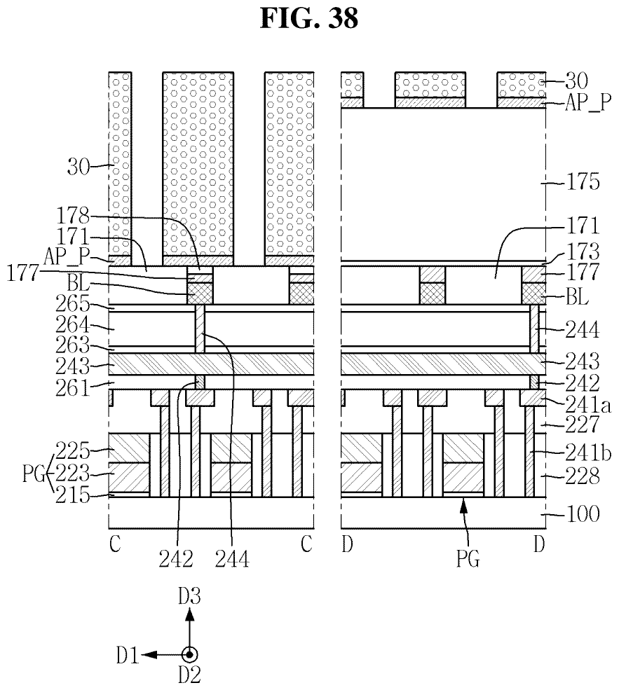

Referring to FIG. 37 and FIG. 38, a sacrificial film 30 may be formed on the pre-channel structure AP_P.

The sacrificial film 30 may be formed on the pre-channel structure AP_P. The sacrificial film 30 may fill the channel trench CH_T. The sacrificial film 30 may be made of an insulating material or silicon oxide and may be formed using SOG (Spin On Glass). However, example embodiments of the present disclosure are not limited thereto.

Subsequently, a mask pattern may be formed on the sacrificial film 30 and the pre-channel structure AP_P. Using the mask pattern as an etch mask, the sacrificial film 30 and the pre-channel structure AP_P may be etched. A portion of the pre-channel structure AP_P and a portion of the sacrificial film 30 on the cell lower insulating film 171 may be removed. Thus, the sacrificial film 30 and the pre-channel structure AP_P may be spaced apart from each other in the first direction D1.

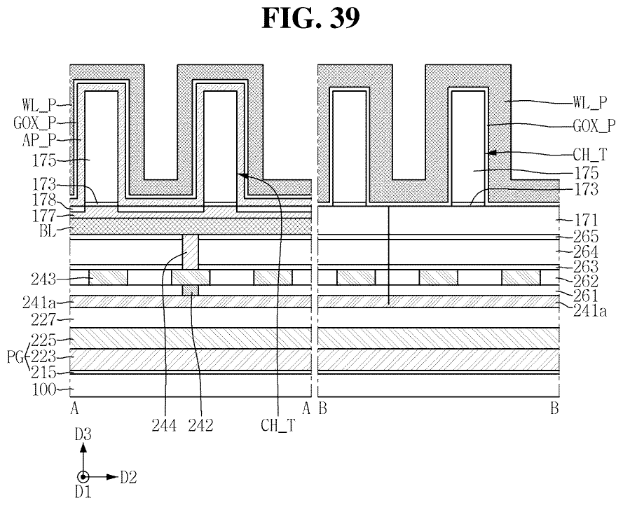

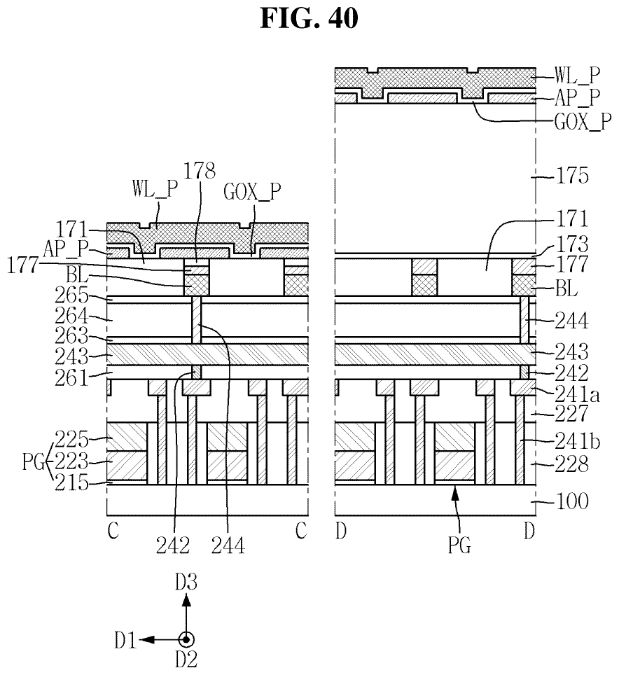

Referring to FIG. 39 and FIG. 40, the sacrificial film 30 may be removed, and a pre-gate insulating film GOX_P and a pre-word-line WL_P may be formed.

For example, the sacrificial film 30 may be removed, and the pre-channel structure AP_P, a portion of the cell lower insulating film 171, and the protruding insulating pattern 175 may be exposed. Subsequently, the pre-gate insulating film GOX_P and the pre-word-line WL_P may be formed sequentially on the pre-channel structure AP_P, the cell lower insulating film 171, and the protruding insulating pattern 175.

The pre-gate insulating film GOX_P may be formed using at least one of physical vapor deposition (PVD), thermal chemical vapor deposition (thermal CVD), low pressure chemical vapor deposition (LP-CVD), plasma enhanced chemical vapor deposition (PECVD), or atomic layer deposition (ALD). However, example embodiments of the present disclosure are not limited thereto.

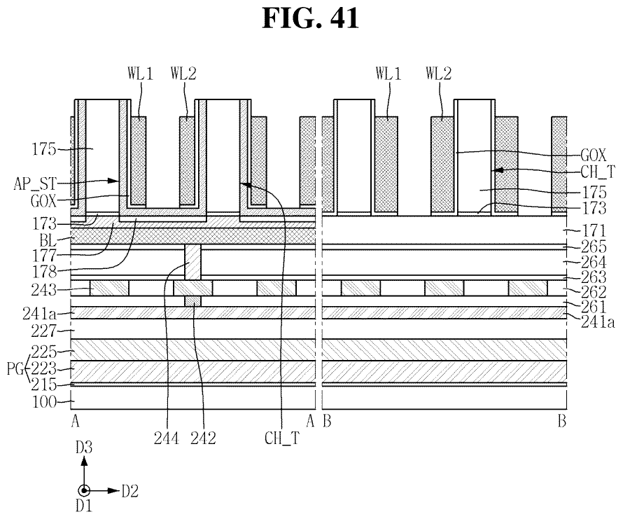

Referring to FIG. 41, the channel structure AP_ST, the first word-line WL1, and the second word-line WL2 may be formed.

For example, an anisotropic etching process may be performed on the pre-word-line WL_P. During the anisotropic etching process on the pre-word-line WL_P, a portion of the pre-word-line WL_P on the upper surface of the protruding insulating pattern 175 may be removed, such that the first word-line WL1 and the second word-line WL2 may be formed. In addition, a portion of the pre-gate insulating film GOX_P and a portion of the pre-channel structure AP_P on the upper surface of the protruding insulating pattern 175 may be removed, so that the gate insulating film GOX and the channel structure AP_ST may be formed, respectively.

In some example embodiments, during the anisotropic etching process on the pre-word-line WL_P, a portion of the gate insulating film GOX may be etched. Thus, a portion of the gate insulating film GOX between the first word-line WL1 and the channel structure AP_ST may be isolated from a portion of the gate insulating film GOX between the second word-line WL2 and the channel structure AP_ST.

In some example embodiments, during the anisotropic etching process on the pre-word-line WL_P, a portion of the channel structure AP_ST between the first word-line WL1 and the second word-line WL2 may be etched. Thus, the channel structure AP_ST may be divided into the first channel pattern AP1 and the second channel pattern AP2 in FIG. 14.

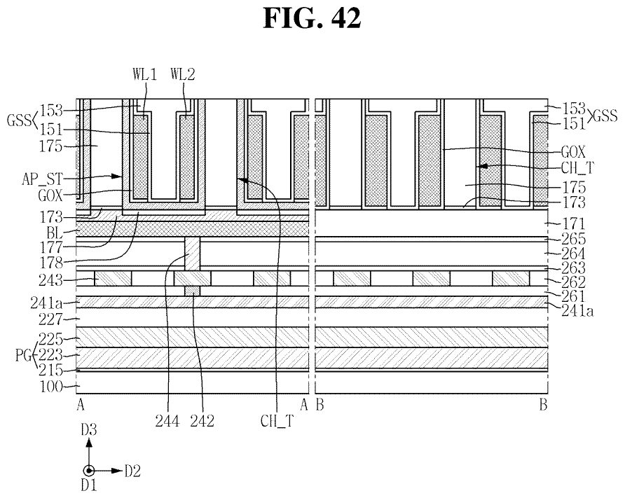

Referring to FIG. 42, the gate isolation pattern GSS may be formed on the first word-line WL1 and the second word-line WL2. The gate isolation pattern GSS may fill the channel trench CH_T.

For example, the gate isolation liner 151 may be formed according to a profile of the first word-line WL1 and a profile of the second word-line WL2. The gate isolation liner 151 may further be formed on the upper surface of the protruding insulating pattern 175.

A pre-filling film may be formed on the gate isolation liner 151. The pre-filling film may further be formed on the upper surface of the protruding insulating pattern 175. A portion of the pre-filling film may be removed, such that the gate isolation filling film 153 may be formed on the gate isolation liner 151.

Referring to FIG. 2 and FIG. 3, a portion of the channel structure AP_ST may be removed, such that a vertical level of the uppermost surface of the channel structure AP_ST may be lower than that of the upper surface of the protruding insulating pattern 175. Subsequently, a pre-landing pad film may be formed on the protruding insulating pattern 175, the gate isolation pattern GSS, and the channel structure AP_ST. The pre-landing pad film may be patterned such that landing pads LP may be formed on the channel structure AP_ST.

Subsequently, the data storage pattern DSP may be formed on the landing pad LP. The data storage pattern DSP may be connected to the channel structure AP_ST and may be formed on the gate isolation pattern GSS.

Although some example embodiments of the present disclosure have been described with reference to the accompanying drawings, the present disclosure is not limited to the above example embodiments, but may be implemented in various different forms. A person skilled in the art may appreciate that the present disclosure may be practiced in other concrete forms without changing the technical spirit or essential characteristics of the present disclosure. Therefore, it should be appreciated that the example embodiments as described above is not restrictive but illustrative in all respects.

What is claimed is:

1. A semiconductor memory device comprising:
a bit-line on a substrate and extending in a first direction;
a liner film on the bit-line and extending along an upper surface of the bit-line;
a channel structure on the liner film, the channel structure including a first channel pattern and a second channel pattern that are spaced apart from each other in the first direction;
a plurality of liner patterns between the liner film and the channel structure, each of the liner patterns overlapping the channel structure when viewed in a plan view;
a first word-line between the first channel pattern and the second channel pattern, the first word-line extending in a second direction intersecting the first direction;
a second word-line between the first channel pattern and the second channel pattern, the second word-line extending in the second direction, the second word-line spaced apart from the first word-line in the first direction; and
a first capacitor and a second capacitor on the first channel pattern and the second channel pattern, respectively, the first capacitor and the second capacitor connected to the first channel pattern and the second channel pattern, respectively.

2. The semiconductor memory device of claim 1, wherein the liner patterns are spaced apart from each other in the first direction.

3. The semiconductor memory device of claim 1, further comprising:
a protruding insulating pattern on the liner film,
wherein the liner film includes a first surface contacting the liner patterns in a third direction, the third direction being a thickness direction of the bit-line, and a second surface overlapping the protruding insulating pattern in the third direction, and
wherein a vertical length between the upper surface of the bit-line and the first surface of the liner film is smaller than a vertical length between the upper surface of the bit-line and the second surface of the liner film.

4. The semiconductor memory device of claim 3, wherein the protruding insulating pattern includes an upper surface and a bottom surface opposite to the upper surface,
wherein at least a portion of the bottom surface of the protruding insulating pattern does not overlap the liner patterns in the third direction.

5. The semiconductor memory device of claim 1, wherein an upper surface of the liner film and upper surfaces of the liner patterns are coplanar with each other.

6. The semiconductor memory device of claim 1, further comprising:
a gate insulating film between the first channel pattern and the first word-line,
wherein a vertical length from each of the liner patterns to a top level of the gate insulating film is greater than a vertical length from the each of the liner patterns to a top level of the first channel pattern.

7. The semiconductor memory device of claim 1, further comprising:
a gate isolation pattern on the bit-line, the gate isolation pattern isolating the first word-line and the second word-line from each other,
wherein the first channel pattern and the second channel pattern are connected to each other via a connection channel pattern, and
wherein the gate isolation pattern is on the connection channel pattern.

8. The semiconductor memory device of claim 7, wherein each of the first channel pattern, the second channel pattern, and the connection channel pattern is in direct contact with a corresponding one of the liner patterns.

9. The semiconductor memory device of claim 1, wherein the liner film includes titanium nitride, and
wherein each of the liner patterns includes titanium oxide doped with at least one of niobium or titanium oxide that is seeded with silicon.

10. The semiconductor memory device of claim 9, wherein the liner patterns include a first liner pattern and a second liner pattern on the first liner pattern,
wherein the first liner pattern includes titanium oxide seeded with silicon, and
wherein the second liner pattern includes niobium-doped titanium oxide.

11. The semiconductor memory device of claim 1, wherein each of the first channel pattern and the second channel pattern includes a metal oxide, and
wherein the metal oxide includes one of IGZO, impurity-doped IZO, InO, ZnO, GaO, SnO, AZO, and ITO.

12. The semiconductor memory device of claim 1, further comprising:
a gate isolation pattern on a corresponding one of the liner patterns, the gate isolation pattern isolating the first word-line and the second word-line from each other,
wherein the gate isolation pattern is in contact with the corresponding one of the liner patterns.

13. The semiconductor memory device of claim 1, wherein the bit-line, the liner film, the liner patterns, and the channel structure are sequentially stacked in a third direction, the third direction being a thickness direction of the bit-line.

14. A semiconductor memory device comprising:
a bit-line on a substrate and extending in a first direction, the bit-line including first metal;
a liner film on the bit-line and extending along an upper surface of the bit-line, the liner film including second metal different from the first metal;
a channel structure on the liner film, the channel structure including a first channel pattern and a second channel pattern that are spaced apart from each other in the first direction;
a plurality of liner patterns between the liner film and the channel structure, each of the liner patterns including oxide of the second metal;
a first word-line between the first channel pattern and the second channel pattern, the first word-line extending in a second direction intersecting the first direction;
a second word-line between the first channel pattern and the second channel pattern, the second word-line extending in the second direction, the second word-line spaced apart from the first word-line in the first direction; and
a first capacitor and a second capacitor on the first channel pattern and the second channel pattern, respectively, the first capacitor and the second capacitor connected to the first channel pattern and the second channel pattern, respectively.

15. The semiconductor memory device of claim 14, further comprising:
a protruding insulating pattern on the liner film,
wherein the liner film includes a first surface contacting the liner patterns in a third direction, the third direction being a thickness direction of the bit-line, and a second surface overlapping the protruding insulating pattern in the third direction,
wherein a vertical length between the upper surface of the bit-line and the first surface of the liner film is smaller than a vertical length between the upper surface of the bit-line and the second surface of the liner film.

16. The semiconductor memory device of claim 15, wherein the protruding insulating pattern includes an upper surface and a bottom surface opposite to each other,
wherein at least a portion of the bottom surface of the protruding insulating pattern does not overlap the liner patterns in the third direction.

17. The semiconductor memory device of claim 14, wherein the channel structure further includes a connection channel pattern connecting the first channel pattern and the second channel pattern to each other,
wherein each of the first channel pattern, the second channel pattern, and the connection channel pattern are in direct contact with a corresponding one of the liner patterns.

18. The semiconductor memory device of claim 17, further comprising:
a gate isolation pattern on the bit-line, the gate isolation pattern isolating the first word-line and the second word-line from each other,
wherein the gate isolation pattern is on the connection channel pattern.

19. The semiconductor memory device of claim 14, wherein the liner film includes titanium nitride, and
wherein each of the liner patterns includes niobium-doped titanium oxide.

20. A semiconductor memory device comprising:
a peripheral gate structure on a substrate;
a bit-line on the peripheral gate structure, the a bit-line extending in a first direction, the bit-line including first metal;
a liner film on the bit-line, the liner film extending along an upper surface of the bit-line, the liner film including second metal different from the first metal;
a channel structure on the liner film, the channel structure including a first channel pattern and a second channel pattern that are spaced apart from each other in the first direction;
a liner pattern between the liner film and the channel structure, the liner pattern including oxide of the second metal doped with niobium;
a first word-line between the first channel pattern and the second channel pattern, the first word-line extending in a second direction intersecting the first direction;
a second word-line between the first channel pattern and the second channel pattern, and the second word-line extending in the second direction, the second word-line spaced apart from the first word-line in the first direction;
a first capacitor and a second capacitor on the first channel pattern and the second channel pattern, respectively, the first capacitor and the second capacitor connected to the first channel pattern and the second channel pattern, respectively; and
a gate isolation pattern on the liner pattern, the gate isolation pattern isolating the first word-line and the second word-line from each other.
